(19) United States
(12) Patent Application Publication
(10) Pub. No.: US 2021/0024674 A1
(43) Pub. Date: Jan. 28, 2021

(54) POLYMER COMPOUND, COMPOSITION, INSULATING LAYER, AND ORGANIC THIN FILM TRANSISTOR

(71) Applicant: SUMITOMO CHEMICAL COMPANY, LIMITED, Tokyo (JP)

(72) Inventors: Isao YAHAGI, Tsukuba-shi (JP); Yuki YOKOI, Tsukuba-shi (JP)

(73) Assignee: SUMITOMO CHEMICAL COMPANY, LIMITED, Tokyo (JP)

(21) Appl. No.: 15/999,062

(22) PCT Filed: Feb. 15, 2017
(86) PCT No.: PCT/JP2017/005407

§ 371 Date: Aug. 17, 2018

(30) Foreign Application Priority Data
Feb. 18, 2016 (JP) 2016-028920

(51) Int. Cl. C08F 220/22; C08J 5/18; H01L 51/05; C08F 220/36

(52) U.S. Cl. CPC C08F 220/22; C08F 220/36; H01L 51/0512; C08J 5/18

(57) ABSTRACT

Provided is an organic thin film transistor having a high carrier mobility. Provided is a polymer compound, including: a repeating unit represented by the following formula (1); and at least two repeating units, the repeating units being at least one selected from the group consisting of a repeating unit having a blocked isocyanato group and a repeating unit having a blocked isothiocyanato group,

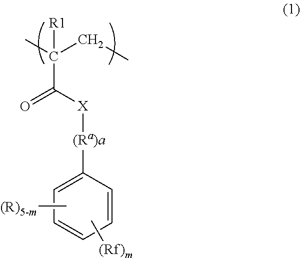

wherein, in formula (1), R¹ is a hydrogen atom or a methyl group; R is a hydrogen atom or a monovalent organic group having 1 to 20 carbon atoms; Rf is a fluorine atom or a monovalent organic group including a fluorine atom; R^{a} is a divalent organic group having 1 to 20 carbon atoms, and a hydrogen atom in the divalent organic group may be substituted with a fluorine atom; X is an oxygen atom or a group represented by —NR⁷—; R⁷ is a hydrogen atom or a monovalent organic group having 1 to 20 carbon atoms; a is an integer of 0 to 20; and m is an integer of 1 to 5.

### TECHNICAL FIELD

The present invention relates to a polymer compound to be used for insulating layers such as a gate insulating layer of an organic thin film transistor, a composition comprising the polymer compound, and an insulating layer and an organic thin film transistor using the polymer compound or the composition.

### BACKGROUND ART

Organic thin film field effect transistors (organic thin film transistors) using an organic material ran he manufactured by a manufacturing process at lower temperatures than inorganic field effect transistors using an inorganic material. Therefore, a plastic substrate or a plastic film can be used as a substrate of an organic thin film transistor, and this allows the manufacturing of a transistor that is lighter in weight and more resistant to breakage.

In some cases, an organic thin film transistor can be manufactured by applying and printing of a liquid (a solution, a dispersion liquid) comprising an organic material. In this case, an organic thin film transistor array having a large area can be manufactured at low costs.

Furthermore, since there are a wide variety of materials which can be used for the study of organic thin film transistors, the characteristics of an organic thin film transistor can be fundamentally changed by appropriately selecting a material from various materials having different molecular structures. Therefore, an appropriate combination of materials having different functions allows the achievement of an electronic device using an organic thin film transistor having such various functions that cannot be achieved by a field effect transistor using an inorganic material.

In a field effect transistor, a voltage (gate voltage) applied to a gate electrode acts on a semiconductor layer via a gate insulating layer to control the turning on and off of a drain current. Therefore, a material of a gate insulating layer used for an organic thin film transistor is required to have high electrical-breakdown strength when formed into a thin film.

Furthermore, particularly in a bottom-gate type organic thin film transistor, an organic semiconductor layer is provided so as to overlap a gate insulating layer. Therefore, a material of the gate insulating layer is required to have high affinity for the organic semiconductor layer for the purpose of forming a good interface with the organic semiconductor layer.

Various materials of an insulating layer used for organic thin film transistors have ever been studied.

For example, Patent Document 1 below describes a thermosetting resin composition comprising a fluorine atom as a material of a gate insulating layer of an organic thin film transistor. Patent Document 1 below describes that the organic thin film transistor comprising the gate insulating layer formed using this material has low hysteresis and stable electrical characteristics.

### RELATED ART DOCUMENTS

### Patent Document

Patent Document 1: JP 5479817 B

### DISCLOSURE OF INVENTION

### Problem to be Solved by the Invention

However, in consideration of the use of an organic thin film transistor as, for example, a drive element to drive a light emitting element such as an organic electroluminescent element (organic EL element), it is necessary to further improve the carrier mobility of the organic thin film transistor.

Therefore, an object of the present invention is to provide an organic thin film transistor having a higher carrier mobility.

### Means for Solving Problem

Namely, the present invention provides the following [1] to [10].

[1] A polymer compound, comprising:

a repeating unit represented by the following formula (1); and

at least two repeating units, the repeating units being at least one selected from the group consisting of a repeating unit having a blocked isocyanato group and a repeating unit having a blocked isothiocyanato group,

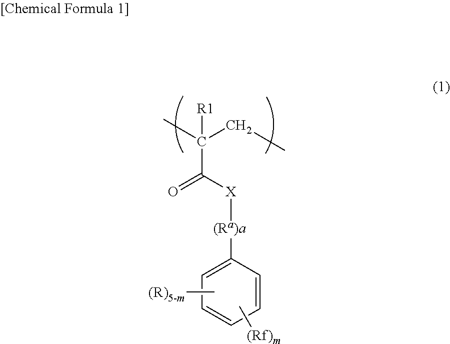

wherein, in formula (1), R¹ is a hydrogen atom or a methyl group; R is a hydrogen atom or a monovalent organic group having 1 to 20 carbon atoms; Rf is a fluorine atom or a monovalent organic group comprising a fluorine atom; R^{a} is a divalent organic group having 1 to 20 carbon atoms, and a hydrogen atom in the divalent organic group may be substituted with a fluorine atom; X is an oxygen atom or a group represented by —NR⁷—; R⁷ is a hydrogen atom or a monovalent organic group having 1 to 20 carbon atoms; a is an integer of 0 to 20; m is an integer of 1 to 5; when R^{a} is plurally present, they may be different from each other; when R is plurally present, they may be different from each other; and when Rf is plurally present, they may be different from each other.

[2] The polymer compound according to [1], further comprising at least one repeating unit selected from the group consisting of a repeating unit having an organic group represented by the following formula (2) and a repeating unit having an organic group represented by the following formula (3):

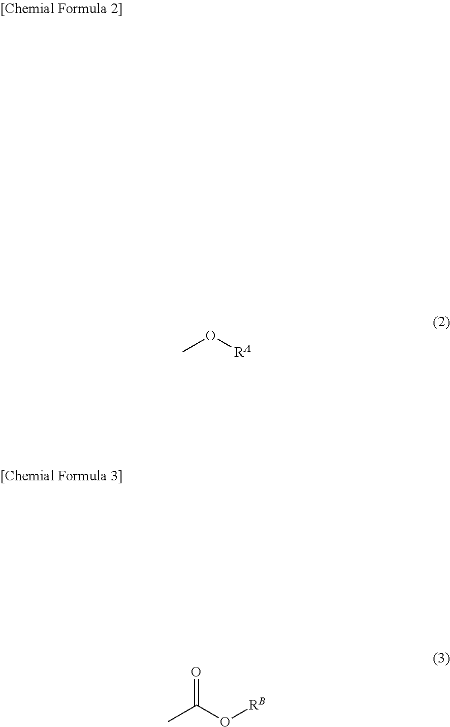

wherein, in formulae (2) and (3), R^{A} and R⁵ are each at least one monovalent organic group selected from the group consisting of a monovalent organic group represented by the following formula (4) and a monovalent organic group represented by the following formula (5):

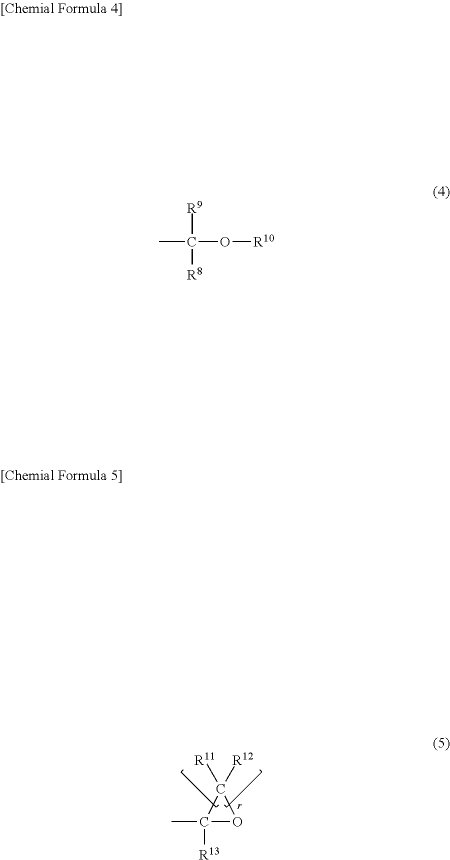

wherein, in formulae (4) and (5), R⁸, R⁹, R¹⁰, R¹¹, R¹², and R¹³ are each independently a hydrogen atom or a monovalent organic group having 1 to 20 carbon atoms; and r is an integer of 1 to 20.

[3] The polymer compound according to [1] or [2], wherein the blocked isocyanato group or the blocked isothiocyanato group is a group represented by the following formula (6) or a group represented by the following formula (7):

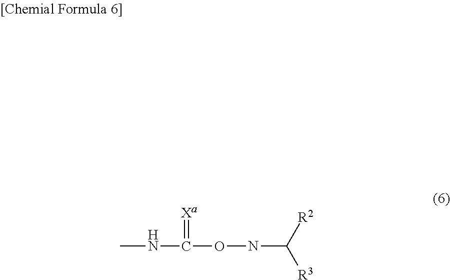

wherein, in formula (6), X^{a} is an oxygen atom or a sulfur atom; and R² and R³ may be different from each other and are each a hydrogen atom or a monovalent organic group having 1 to 20 carbon atoms,

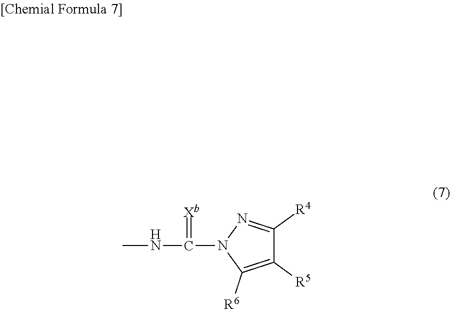

wherein, in formula (7), X^{b} is an oxygen atom or a sulfur atom; and R⁴, R⁵, and R⁶ may be different from each other and are each a hydrogen atom or a monovalent organic group having 1 to 20 carbon atoms.

[4] A composition, comprising the polymer compound according to any one of [1] to [3].

[5] The composition according to [4], further comprising at least one compound selected from the group consisting of a low molecular compound comprising at least two active hydrogens and a polymer compound comprising at least two, active hydrogens.

[6] A cured film of the composition according to [4] or [5].

[7] An electronic device, comprising the film according to [6].

[8] The electronic device according to [7], wherein the electronic device is an organic thin film transistor.

[9] An organic thin film transistor, comprising the film according to [6] as a gate insulating layer.

[10] The organic thin film transistor according to [9], further comprising the film according to ([6] as an overcoat layer.

### Effect Of The Invention

When a polymer compound of the present invention and a composition comprising the polymer compound are used particularly as a material of a gate insulating layer, an organic thin film transistor can have a higher carrier mobility.

### BRIEF DESCRIPTION OF DRAWINGS

FIG. 1 is a schematic diagram illustrating a structure of a bottom-gate top-contact type organic thin film transistor according to a first embodiment of the present invention.

FIG. 2 is a schematic diagram illustrating a structure of a bottom-gate bottom-contact type organic thin film transistor according to a second embodiment of the present invention.

### DESCRIPTION OF EMBODIMENTS

Next, embodiments of the present invention will be described in more details. It should be noted that the drawings to be referred merely schematically illustrate the shapes, sizes, and arrangements of constituents to the extent that the invention can be understood. The present invention is not limited by the following description, and the constituents can be changed as appropriate without departing from the scope of the present invention. In the drawings to be used for the following description, the same constituents are denoted with the same numerals and overlapping description thereof are sometimes omitted. Furthermore, configurations according to the embodiments of the present invention are not necessarily manufactured or used in the arrangements illustrated in the drawings.

It should be noted that, in the specification, a “polymer compound” refers to a compound comprising a plurality of structural units (repeating units) that may be different from each other in a molecule, and examples of the “polymer compound” include what is called a dimer. In the specification, a “low-molecular compound” refers to a compound not comprising a plurality of repeating units in a molecule.

Explanation of Common Term

Terms commonly used in the specification have the following meanings unless otherwise stated.

A “monovalent organic group having 1 to 20 carbon atoms” may be linear, branched, or cyclic, and may be saturated or unsaturated.

Examples of the monovalent organic group having 1 to 20 carbon atoms may include a linear hydrocarbon group having 1 to 20 carbon atoms, a branched hydrocarbon group having 3 to 20 carbon atoms, a cyclic hydrocarbon group having 3 to 20 carbon atoms, a aromatic hydrocarbon group having 6 to 20 carbon atoms, a alkoxy group having 1 to 20 carbon atoms, a aryloxy group having 6 to 20 carbon atoms, a acyl group having 2 to 20 carbon atoms, a alkoxycarbonyl group having 2 to 20 carbon atoms, and a aryloxy carbonyl group having 7 to 20 carbon atoms, and preferably may be a linear hydrocarbon group having 1 to 6 carbon atoms, a branched hydrocarbon group having 3 to 6 carbon atoms, a cyclic hydrocarbon group having 3 to 6 carbon atoms, a aromatic hydrocarbon group having 6 to 20 carbon atoms, a alkoxy group having 1 to 6 carbon atoms, a aryloxy group having 6 to 20 carbon atoms, a acyl group having 2 to 7 carbon atoms, a alkoxycarbonyl group having 2 to 7 carbon atoms, and a aryloxy carbonyl group having 7 to 20 carbon atoms.

A hydrogen atom comprised in the groups, namely, the linear hydrocarbon group having 1 to 20 carbon atoms, the branched hydrocarbon group having 3 to 20 carbon atoms, the cyclic hydrocarbon group having 3 to 20 carbon atoms, the alkoxy group having 1 to 20 carbon atoms, the aryloxy group having 6 to 20 carbon atoms, the acyl group having 2 to 20 carbon atoms, the alkoxycarbonyl group having 2 to 20 carbon atoms, and the aryloxy carbonyl group having 7 to 20 carbon atoms is optionally substituted with a halogen atom.

A hydrogen atom in the aromatic hydrocarbon group having 6 to 20 carbon atoms is optionally substituted with a monovalent organic group or a halogen atom.

Specific examples of the monovalent organic group having 1 to 20 carbon atoms may include a methyl group, an ethyl group, a propyl group, a butyl group, a pentyl group, a hexyl group, an isopropyl group, an isobutyl group, a tert-butyl group, a cyclopropyl group, a cyclobutyl group, a cyclopentyl group, a cyclohexyl group, a cyclopentynyl group, a cyclohexynyl group, a trifluoromethyl group, a trifluoroethyl group, a phenyl group, a naphthyl group, an anthryl group, a tolyl group, a xylyl group, a dimethylphenyl group, a trimethylphenyl group, an ethylphenyl group, a diethylphenyl group, a triethylphenyl group, a propylphenyl group, a butylphenyl group, a methylnaphthyl group, a dimethylnaphthyl group, a trimethylnaphthyl group, a vinylnaphthyl group, an ethenylnaphthyl group, a methylanthryl group, an ethylanthryl group, a pentafluorophenyl group, a trifluoromethylphenyl group, a chlorophenyl group, a bromophenyl group, a methoxy group, an ethoxy group, a phenoxy group, an acetyl group, a benzoyl group, a methoxycarbonyl group, and a phenoxycarbonyl group.

As the monovalent organic group having 1 to 20 carbon atoms, an alkyl group is preferred.

A “divalent organic group having 1 to 20 carbon atoms” may be linear, branched, or cyclic, and may be an aliphatic hydrocarbon group or an aromatic hydrocarbon group. Examples of the divalent organic group having 1 to 20 carbon atoms may include a divalent linear aliphatic hydrocarbon group having 1 to 20 carbon atoms, a divalent branched aliphatic hydrocarbon group having 3 to 20 carbon atoms, a divalent cyclic hydrocarbon group having 3 to 20 carbon atoms, and a divalent aromatic hydrocarbon group having 6 to 20 carbon atoms optionally substituted with, for example, a monovalent organic group. Among them, a divalent linear aliphatic hydrocarbon group having 1 to 6 carbon atoms, a divalent branched aliphatic hydrocarbon group having 3 to 6 carbon atoms, a divalent cyclic hydrocarbon group having 3 to 6 carbon atoms, and a divalent aromatic hydrocarbon group having 6 to 20 carbon atoms optionally substituted, for example, with an alkyl group are preferred as the divalent organic group having 1 to 20 carbon atoms.

Specific examples of the divalent aliphatic hydrocarbon group and the divalent cyclic hydrocarbon group may include a methylene group, an ethylene group, a propylene group, a butylene group, a pentylene group, a hexylene group, an isopropylene group, an isobutylene group, a dimethylpropylene group, a cyclopropylene group, a cyclobutylene group, a cyclopentylene group, and a cyclohexylene group.

Specific examples of the divalent aromatic hydrocarbon group having 6 to 20 carbon atoms may include a phenylene group, a naphthylene group, an anthrylene group, a dimethylphenylene group, a trimethylphenylene group, an ethylenephenylene group, a diethylenephenylene group, a triethylenephenylene group, a propylenephenylene group, a butylenephenylene group, a methylnaphthylene group, a dimethylnaphthylene group, a trimethylnaphthylene group, a vinylnaphthylene group, an ethenylnaphthylene group, a methylanthrylene group, and an ethylanthrylene group.

A “halogen atom” is a fluorine atom, a chlorine atom, a bromine atom, or an iodine atom.

Polymer Compound

A polymer compound of the present invention is a polymer compound comprising a repeating unit represented by the following formula (1), and comprising at least two repeating units, the repeating units being at least one selected from the group consisting of a repeating unit having a blocked isocyanato group and a repeating unit having a blocked isothiocyanato group (hereinafter, sometimes referred to as a “polymer compound (A)”).

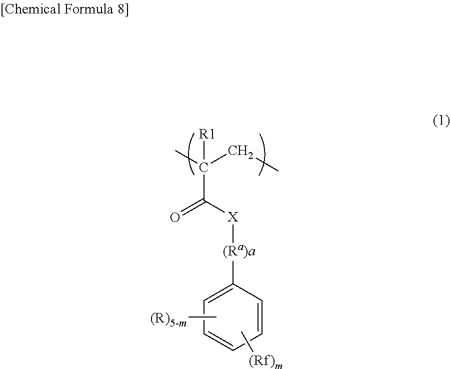

In the formula (1), R¹ is a hydrogen atom or a methyl group. R is a hydrogen atom or a monovalent organic group having 1 to 20 carbon atoms. Rf is a fluorine atom or a monovalent organic group comprising a fluorine atom. R^{a} is a divalent organic group having 1 to 20 carbon atoms, and a hydrogen atom in the divalent organic group is optionally substituted with a fluorine atom. X is an oxygen atom or a group represented by —NR⁷—. R⁷ is a hydrogen atom or a monovalent organic group having 1 to 20 carbon atoms. a is an integer of 0 to 20, and m is an integer of 1 to 5. When R^{a} is plurally present, they may be different from each other. When R is plurally present, they may be different from each other. When Rf is plurally present, they may be different from each other.

<Polymer Compound (A)>

First, the polymer compound (A) will be specifically described. The polymer compound (A) comprises a repeating unit represented by the above-mentioned formula (1), as a repeating unit comprising a fluorine atom.

(Repeating Unit Represented by Formula (1))

In the formula (1), R¹ is a hydrogen atom or a methyl group. In one embodiment of the present invention, R¹ is preferably a methyl group.

In the formula (1), R is a hydrogen atom or a monovalent organic group having 1 to 20 carbon atoms. When R is plurally present, the Rs may be different from each other.

In the formula (1), Rf is a fluorine atom or a monovalent organic group comprising a fluorine atom, and specifically, is a fluorine atom or a monovalent organic group having 1 to 20 carbon atoms comprising a fluorine atom in which at least one hydrogen atom is substituted with a fluorine atom. In one embodiment of the present invention, Rf is preferably a fluorine atom. When Rf is plurally present, they may be different from each other.

In the formula (1), R^{a} is a divalent organic group having 1 to 20 carbon atoms. A hydrogen atom in the divalent organic group is optionally substituted with a fluorine atom. a is an integer of 0 to 20. In one embodiment of the present invention, a is preferably 1. When R^{a} is plurally present, they may be different from each other.

In the formula (1), X is an oxygen atom or a group represented by —NR⁷—. Here, R⁷ is a hydrogen atom or a monovalent organic group having 1 to 20 carbon atoms. In one embodiment of the present invention, X is preferably an oxygen atom.

m is an integer of 1 to 5. In one embodiment of the present invention, m is preferably 5.

(At Least One Repeating Unit Selected from Group Consisting of Repeating Unit Having Organic Group Represented by Formula (2) and Repeating Unit Having Organic Group Represented by Formula (3))

The polymer compound (A) is preferably a polymer compound (A-1) further comprising at least one repeating unit selected from the group consisting of a repeating unit having an organic group represented by the following formula (2) and a repeating unit having an organic group represented by the following formula (3).

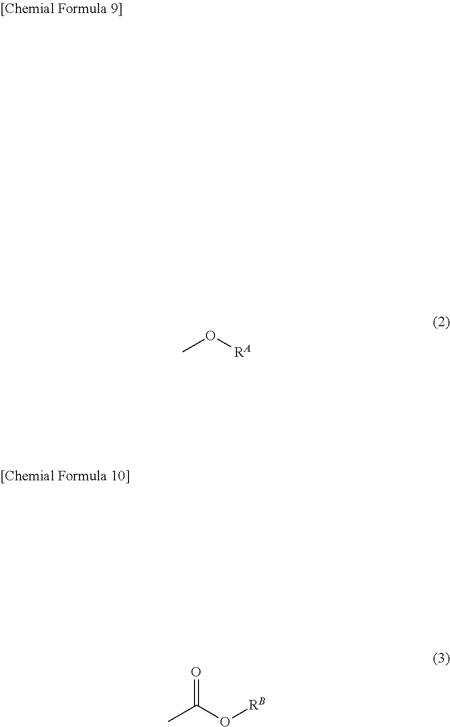

In the formulae (2) and (3), R^{A} and R^{B} are each at least one monovalent organic group selected from the group consisting of a monovalent organic group represented by the following formula (4) and a monovalent organic group represented by the following formula (5).

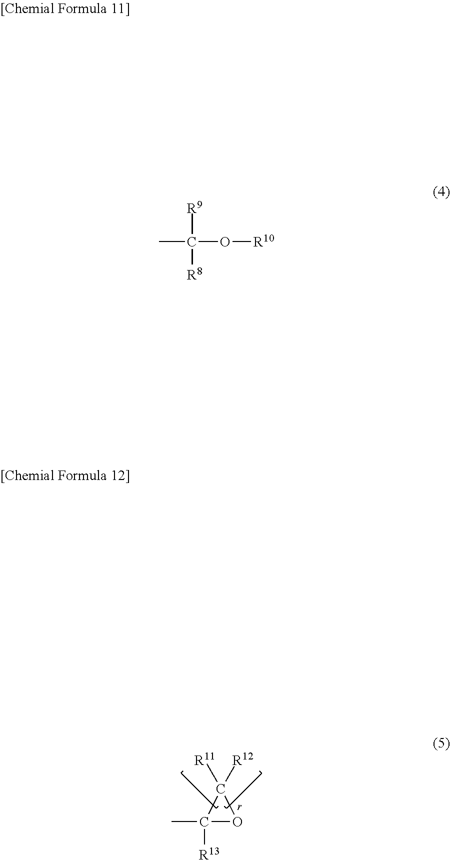

In the formulae (4) and (5), R⁸, R⁹, R¹⁰, R¹¹, R¹², and R¹³ are each independently a hydrogen atom or a monovalent organic group having 1 to 20 carbon atoms. r is an integer of 1 to 20.

Definitions and specific examples of the monovalent organic groups serving as R⁸, R⁹, R¹¹, R¹², and R¹³ are the same as the above-described definition and specific examples of the organic group serving as R. In one embodiment, in the formulae (4) and (5), R⁸, R¹¹, R¹², and R¹³ are each preferably a hydrogen atom, R⁹ is preferably a methyl group, R¹⁰ is preferably an ethyl group, and r is preferably 4.

Examples of the monovalent organic group represented by the formula (4) may include a methoxymethyl group, a methoxyethoxymethyl group, a 1-ethoxyethyl group, 2-ethoxyethyl group, a 1-methoxypropyl group, and a 1-ethoxypropyl group.

Examples of the monovalent organic group represented by the formula (5) may include an oxiranyl group, an oxetanyl group, a hydrofuranyl group, a hydropyranyl group, a hydrooxepinyl group, and a hydrooxocinyl group. These groups optionally have a substituent.

Here the hydrofuranyl group denotes a group in which one hydrogen atom directly bonded to a carbon atom being a constituent of the ring of dihydrofuran or tetrahydrofuran is eliminated. Examples of the substituent that the hydrofuranyl group optionally has may include an alkyl group, a cycloalkyl group, an alkoxy group, a cycloalkoxy group, and a hydroxyl group. Examples of the hydrofuranyl group may include a dihydrofuranyl group and a tetrahydrofuranyl group.

The hydropyranyl group denotes a group in which one hydrogen atom directly bonded to a carbon atom being a constituent of the ring of dihydropyran or tetrahydropyran is eliminated. Examples of the substituent that the hydropyranyl group optionally has may include an alkyl group, a cycloalkyl group, an alkoxy group, a cycloalkoxy group, and a hydroxyl group. Examples of the hydropyranyl group may include a dihydropyranyl group, a tetrahydropyranyl group, and a 4-methoxytetrahydropyranyl group.

The hydrooxepinyl group denotes a group in which one hydrogen atom directly bonded to a carbon atom being a constituent of the ring of 2,3-dihydrooxepine, 2,3,4,5-tetrahydrooxepine, 2,3,6,7-tetrahydrooxepine, or hexahydrooxepine is eliminated. Examples of the substituent that the hydrooxepinyl group optionally has may include an alkyl group, a cycloalkyl group, an alkoxy group, a cycloalkoxy group, and a hydroxyl group. Examples of the hydrooxepinyl group may include a 2,3-dihydrooxepinyl group.

The hydrooxocinyl group denotes a group in which one hydrogen atom directly bonded to a carbon atom being a constituent of the ring of 3,4-dihydro-2H-oxocin, 5,6-dihydro-2H-oxocin, 7,8-dihydro-2H-oxocin, 3,4,5,6-tetrahydro-2H-oxocin, 5,6,7,8-tetrahydro-2H-oxocin, or hexahydro-2H-oxocin is elominated. Examples of the substituent that the hydrooxocinyl group optionally has may include an alkyl group, a cycloalkyl group, an alkoxy group, a cycloalkoxy group, and a hydroxyl group. Examples of the hydrooxocinyl group may include a 3,4-dihydro-2H-oxocinyl group.

Examples of the organic group represented by the formula (2) may include a methoxymethyloxy group, a methoxyethoxymethyloxy group, a 1-ethoxyethyloxy group, a 2-ethoxyethyloxy group, a 1-methoxypropyloxy group, and a 1-ethoxypropyloxy group.

Examples of the organic group represented by the formula (3) may include an oxiranyl-2-oxycarbonyl group, an oxetanyl-2-oxycarbonyl group, a 2, 3-dihydrofuranyl-2-oxycarbonyl group, a tetrahydrofuranyl-2-oxycarbonyl group, a 3,4-dihydro-2H-pyranyl-2-oxycarbonyl group, a 3,6-dihydro-2H-pyranyl-2-oxycarbonyl group, a tetrahydropyranyl-2-oxycarbonyl group, a 2,3-dihydrooxepinyl-2-oxycarbonyl group, a 2,3,4,5-tetrahydrooxepinyl-2-oxycarbonyl group, a 2,3,6,7-tetrahydrooxepinyl-2-oxycarbonyl group, a hexahydrooxepinyl-2-oxycarbonyl group, a 3,4-dihydro-2H-oxocinyl-2-oxycarbonyl group, a 5,6-dihydro-2H-oxocinyl-2-oxycarbonyl group, a 7,8-dihydro-2H-oxocinyl-2-oxycarbonyl group, a 3,4,5,6-tetrahydro-2H-oxocinyl-2-oxycarbonyl group, a 5,6,7,8-tetrahydro-2H-oxocinyl-2-oxycarbonyl group, and a hexahydro-2H-oxocinyl-2-oxycarbonyl group.

(At Least One Repeating Unit Selected from Group Consisting of Repeating Unit Having Blocked Isocyanato Group and Repeating Unit Having Blocked Isothiocyanato Group)

As described above, the polymer compound (A) and the polymer compound (A-1) each has a blocked isocyanato group and/or a blocked isothiocyanato group in a molecule.

The blocked isocyanato group or the blocked isothiocyanato group that the polymer compound (A) or the polymer compound (A-1) according to the present invention may have is preferably a group represented by the following formula (6) or the following formula (7).

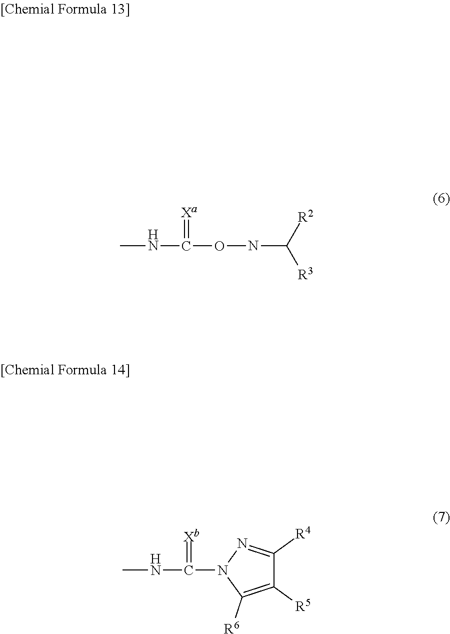

In the formulae (6) and (7), X^{a} and X^{b} are each an oxygen atom or a sulfur atom. R², R³, R⁴, R⁵, and R⁶ may be different from each other, and are each a hydrogen atom or a monovalent organic group having 1 to 20 carbon atoms. Definitions and specific examples of the monovalent organic groups serving as R² to R⁶ are the same as the above-described definition and specific examples of the organic group serving as R.

In one embodiment of the present invention, R² and R³ in the formula (6) are preferably each independently a group selected from the group consisting of a methyl group and an ethyl group. In another embodiment, R⁴ and R⁶ in the formula (7) are preferably a methyl group, and R⁵ is preferably a hydrogen atom.

Examples of the blocked isocyanato group that the polymer compound (A) or the polymer compound (A-1) may have may include an O-(methylideneamino)carboxyamino group, an O-(1-ethylideneamino)carboxyamino group, an O-(1-methylethylideneamino)carboxyamino group, an O-[1-methylpropylideneamino]carboxyamino group, an (N-3,5-dimethylpyrazolylcarbonyl)amino group, an (N-3-ethyl-5-methylpyrazolylcarbonyl)amino group, an (N-3,5-diethylpyrazolylcarbonyl)amino group, an (N-3-propyl-5-methylpyrazolylcarbonyl)amino group, and an (N-3-ethyl-5-propylpyrazolylcarbonyl)amino group.

Examples of the blocked isothiocyanato group that the polymer compound (A) or the polymer compound (A-1) may have may include an O-(methylideneamino)thiocarboxyamino group, an O-(1-ethylideneamino)thiocarboxyamino group, an O-(1-methylethylideneamino)thiocarboxyamino group, an O-[1-methylpropylideneamino]thiocarboxyamino group, an (N-3,5-dimethylpyrazolylthiocarbonyl)amino group, an (N-3-ethyl-5-methylpyrazolylthiocarbonyl)amino group, an (N-3,5-diethylpyrazolylthiocarbonyl)amino group, an (N-3-propyl-5-methylpyrazolylthiocarbonyl)amino group, and an (N-3-ethyl-5-propylpyrazolylthiocarbonyl)amino group.

As at least one group (a first functional group) selected from the group consisting of the blocked isocyanato group and the blocked isothiocyanato group of the polymer compound (A) or the polymer compound (A-1), the blocked isocyanato group is preferred.

In the case where the blocked isocyanato group and/or the blocked isothiocyanato group that the polymer compound (A) or the polymer compound (A-1) has is taken as the first functional group, the first functional group does not react with active hydrogen. However, when electromagnetic wave or heat acts on the first functional group, a second functional group is produced, and the produced second functional group is capable of reacting with active hydrogen. That is, the first functional group is a group in which a protective group derived from a blocking agent is deprotected by an action of electromagnetic wave or heat, whereby a second functional group capable of reacting with active hydrogen is produced.

Here “active hydrogen” denotes a hydrogen atom bonded to an atom other than a carbon atom, such as an oxygen atom, a sulfur atom or a nitrogen atom.

From the viewpoint of maintaining the storage stability of the composition, the second functional group that reacts with active hydrogen is preferably protected (blocked) until a formation step for a gate insulating layer is conducted. That is, the first functional group is preferably a functional group that is dissociated by electromagnetic wave treatment or heat treatment in the formation step for a gate insulating layer to produce the second functional group that reacts with active hydrogen. This allows the first functional group to be present in the composition until the formation step for a gate insulating layer is conducted, and as a result, the storage stability of the composition is improved.

The structure of the at least one repeating unit selected from the group consisting of a repeating unit having a blocked isothiocyanato group and a repeating unit having a blocked isocyanato group is based on the chemical structure of a monomer serving as a raw material of the repeating unit.

It should be noted that the polymer compound (A) or the polymer compound (A-1) may comprise a repeating unit having only a blocked isocyanato group, may comprise a repeating unit having only a blocked isothiocyanato group, may comprise a repeating unit having both a blocked isocyanato group and a blocked isothiocyanato group, or may comprise a combination of two or more selected from a repeating unit having only a blocked isocyanato group, a repeating unit having only a blocked isothiocyanato group, and a repeating unit having both a blocked isocyanato group and a blocked isothiocyanato group.

Hereinafter, examples of the monomer serving as a raw material of the at least one repeating unit selected from a repeating unit having a blocked isocyanato group and a repeating unit having a blocked isothiocyanato group will be described.

Examples of a polymerizable monomer having a blocked isocyanato group or a blocked isothiocyanato group may include a monomer having a blocked isocyanato group or a blocked isothiocyanato group and an unsaturated bond in a molecule.

The polymerizable monomer having a blocked isocyanato group or a blocked isothiocyanato group and an unsaturated bond in a molecule can be produced by reacting a compound having an isocyanato group or an isothiocyanato group and an unsaturated bond in a molecule with a blocking agent. Here the unsaturated bond is preferably an unsaturated double bond.

Examples of the compound having an unsaturated double bond and an isocyanato group in a molecule may include 2-acryloyloxyethylisocyanate, 2-methacryloyloxyethylisocyanate, and 2-(2′-methacryloyloxyethyl) oxyethylisocyanate. Examples of the compound having an unsaturated double bond and an isothiocyanato group in a molecule include 2-acryloyloxyethylisothiocyanate, 2-methacryloyloxyethylisothiocyanate, and 2-(2′-methacryloyloxyethyl) oxyethylisothiocyanate.

Examples of the monomer having an unsaturated double bond and a blocked isocyanato group in a molecule may include 2-[O-[1′-methylpropylideneamino]carboxyamino]ethyl-methacrylate, and 2-[N-[1′, 3′-dimethylpyrazolyl]carboxyamino]ethyl-methacrylate.

The compound having a blocked isocyanato group or the compound having a blocked isothiocyanato group can be produced by, for example, reacting a blocking agent having only one active hydrogen in one molecule, the active hydrogen being capable of reacting with an isocyanato group or an isothiocyanato group, with a compound having an isocyanato group or an isothiocyanato group.

As the blocking agent, a compound capable of being dissociated from an isocyanato group or an isothiocyanato group at 170° C. or lower even after reacting with the isocyanato group or the isothiocyanato group is preferable. Examples of the blocking agent may include alcohol compounds, phenolic compounds, active methylene compounds, mercaptan compounds, acid amide compounds, acid imide compounds, imidazole compounds, urea compounds, oxime compounds, amine compounds, imine compounds, bisulfites, pyridine compounds, and pyrazole compounds. These blocking agents may be used alone or may be used by mixing two or more of them. Preferred examples of the blocking agent may include oxime compounds and pyrazole compounds.

Hereinafter, an applicable blocking agent will be specifically described.

Examples of the alcohol compounds serving as the blocking agent may include methanol, ethanol, propanol, butanol, 2-ethylhexanol, methylcellosolve, butylcellosolve, methylcarbitol, benzyl alcohol, and cyclohexanol.

Examples of the phenolic compounds serving as the blocking agent may include phenol, cresol, ethylphenol, butylphenol, nonylphenol, dinonylphenol, styrenated phenol, and hydroxybenzoic acid esters.

Examples of the active methylene compounds serving as the blocking agent may include dimethyl malonate, diethyl malonate, methyl acetoacetate, ethyl acetoacetate, and acetylacetone.

Examples of the mercaptan compounds serving as the blocking agent may include butyl mercaptan and dodecyl mercaptan.

Examples of the acid amide compounds serving as the blocking agent may include acetanilide, acetic acid amide, ε-caprolactam, δ-valerolactam, and γ-butyrolactam.

Examples of the acid imide compounds serving as the blocking agent may include succinimide and maleimide.

Examples of the imidazole compounds serving as the blocking agent may include imidazole and 2-methylimidazole.

Examples of the urea compounds serving as the blocking agent may include urea, thiourea, and ethyleneurea.

Examples of the oxime compounds serving as the blocking agent may include formaldoxime, acetaldoxime, acetoxime, methylethylketoxime, and cyclohexanone oxime.

Examples of the amine compounds serving as the blocking agent may include diphenylamine, aniline, and carbazole.

Examples of the imine compounds serving as the blocking agent may include ethyleneimine and polyethyleneimine.

Examples of the bisulfites serving as the blocking agent may include sodium bisulfite.

Examples of the pyridine compounds serving as the blocking agent may include 2-hydroxypyridine and 2-hydroxyquinoline.

Examples of the pyrazole compounds serving as the blocking agent may include 3,5-dimethylpyrazole and 3,5-diethylpyrazole.

In the reaction of the compound having an isocyanato group or an isothiocyanato group and an unsaturated bond in a molecule with the blocking agent, an organic solvent and a catalyst can be added as necessary.

The fluorine atom content of the polymer compound (A) or the polymer compound (A-1) is preferably 1% to 60% by mass, more preferably 5% to 50% by mass, and still more preferably 5% to 40% by mass, with respect to the mass of the polymer compound (A) or the polymer compound (A-1).

In particular, an adjustment of the fluorine atom content allows the surface energy of a gate insulating layer to be adjusted to an appropriate range, and as a result, allows a good interface with an organic semiconductor layer to be achieved. With this, the carrier mobility of the organic thin film transistor can be further improved.

When the fluorine atom content is 1% by mass or more, the hysteresis characteristics of the organic thin film transistor can be sufficiently reduced, and, when the fluorine atom content is 60% by mass or less, an affinity for an organic semiconductor layer can be maintained good, and thus, a good interface can be formed when the organic semiconductor layer and a gate insulating layer are joined.

The polymer compound (A) or the polymer compound (A-1) has a weight-average molecular weight of preferably 3,000 to 1,000,000, and more preferably 5,000 to 500,000.

The polymer compound (A) or the polymer compound (A-1) may be linear, branched, or cyclic embodiment.

As described above, the repeating unit represented by the formula (1) that constitutes the polymer compound (A) or the polymer compound (A-1) comprises a fluorine atom. Therefore, it is thought that the gate insulating layer of the organic thin film transistor consisting of a cured product formed by curing the composition comprising the polymer compound (A) or the polymer compound (A-1) has low polarity as a whole, and has less components that is easily polarized when a gate voltage is applied thereto, and thus, the polarization of the gate insulating layer is suppressed. When the polarization of the gate insulating layer is suppressed, the hysteresis of the organic thin film transistor is reduced, which results in an improvement in operation accuracy.

Examples of the polymer compound comprising a repeating unit represented by the formula (1), and comprising two or more repeating units, the repeating units being at least one selected from the group consisting of a repeating unit having a blocked isocyanato group and a repeating unit having a blocked isothiocyanato group may include poly(styrene-co-pentafluorobenzyl methacrylate-co-[2-[O-(1′-methyipropylideneamino)carboxyamino]ethyl-methacrylate]), poly(styrene-co-pentafluorobenzyl methacrylate-co-[2-[1′-(3′, 5′-dimethylpyrazolyl) carboxyamino]ethyl-methacrylate]), poly(styrene-co-pentafluorobenzyl methacrylate-co-acrylonitrile-co-[2-[O-(1′-methylpropylideneamino) carboxyamino]ethyl-methacrylate]), poly(styrene-co-pentafluorobenzyl methacrylate-co-acrylonitrile-co-[2-[1′-(3′, 5′-dimethylpyrazolyl) carboxyamino]ethyl-methacrylate]), poly(styrene-co-pentafluorobenzyl methacrylate-co-acrylonitrile-co-[2-[O-(1′-methyipropylideneamino) carboxyamino]ethyl-methacrylate]-co-allyltrimethygermanium), poly(styrene-co-pentafluorobenzyl methacrylate-co-acrylonitrile-co-[2-[1′-(3′, 5′-dimethylpyrazolyl) carboxyamino]ethyl-methacrylate]-co-allyltrimethygermanium), poly(methyl methacrylate-co-pentafluorobenzyl methacrylate-co-[2-[O-(1′-methyipropylideneamino) carboxyamino]ethyl-methacrylate]), poly(methyl methacrylate-co-pentafluorobenzyl methacrylate-co-[2-[1′-(3′, 5′-dimethylpyrazolyl)carboxyamino]ethyl-methacrylate]), poly(styrene-co-pentafluorobenzyl methacrylate-co-(2,2,2-trifluoroethyl methacrylate)-co-[2-[O-(1′-methyipropylideneamino)carboxyamino]ethyl-methacrylate]), poly(styrene-co-pentafluorobenzyl methacrylate-co-(2,2,2-trifluoroethyl methacrylate)-co-[2-[1′-(3′, 5′-dimethylpyrazolyl)carboxyamino]ethyl-methacrylate]), and poly(styrene-co-4-trifluorobenzyl methacrylate-co-[2-[O-(1′-methylpropylideneamino) carboxyamino]ethyl-methacrylate]).

Examples of the polymer compound comprising a repeating unit represented by the formula (1) and at least one repeating unit selected from the group consisting of a repeating unit having an organic group represented by the formula (2) and a repeating unit having an organic group represented by the formula (3), and comprising two or more repeating units, the repeating units being at least one selected from the group consisting of a repeating unit having a blocked isocyanato group and a repeating unit having a blocked isothiocyanato group may include poly(styrene-co-4-(1-ethoxyethyl)styrene-co-pentafluorobenzyl methacrylate-co-[2-[O-(1′-methylpropylideneamino) carboxyamino]ethyl-methacrylate]), poly(styrene-co-4-(1-ethoxyethyl)styrene-co-pentafluorobenzyl methacrylate-co-[2-[1′-(3′, 5′-dimethylpyrazolyl) carboxyamino]ethyl-methacrylate]), poly(styrene-co-4-(1-ethoxyethyl)styrene-co-pentafluorobenzyl methacrylate-co-acrylonitrile-co-[2-[O-(1′-methylpropylideneamino)carboxyamino]ethyl-methacrylate]), poly(styrene-co-4-(1-ethoxyethyl)styrene-co-pentafluorobenzyl methacrylate-co-acrylonitrile-co-[2-[1′-(3′, 5′-dimethylpyrazolyl)carboxyamino]ethyl-methacrylate]), poly(styrene-co-4-(1-ethoxyethyl)styrene-co-pentafluorobenzyl methacrylate-co-acrylonitrile-co-[2-[O-(1′-methylpropylideneamino)carboxyamino]ethyl-methacrylate]-co-allyltrimethylgermanium), poly(styrene-co-4-(1-ethoxyethyl)styrene-co-pentafluorobenzyl methacrylate-co-acrylonitrile-co-[2-[1′-(3′, 5′-dimethylpyrazolyl) carboxyamino]ethyl-methacrylate]-co-allyltrimethylgermanium), poly(methyl methacrylate-co-4-(1-ethoxyethyl) styrene-co-pentafluorobenzyl methacrylate-co-[2-[O-(1′-methylpropylideneamino)carboxyamino]ethyl-methacrylate]), poly(methyl methacrylate-co-4-(1-ethoxyethyl) styrene-co-pentafluorobenzyl methacrylate-co-[2-[1′-(3′, 5′-dimethylpyrazolyl)carboxyamino]ethyl-methacrylate]), poly(styrene-co-4-(1-ethoxyethyl)styrene-co-pentafluorobenzyl methacrylate-co-(2,2,2-trifluoroethyl methacrylate)-co-[2-[O-(1′-methyipropylideneamino)carboxyamino]ethyl-methacrylate]), poly(styrene-co-4-(1-ethoxyethyl)styrene-co-pentafluorobenzyl methacrylate-co-(2,2,2-trifluoroethyl methacrylate)-co-[2-[1′-(3′, 5′-dimethylpyrazolyl)carboxyamino]ethyl-methacrylate]), poly(styrene-co-4-(1-ethoxyethyl)styrene-co-4-trifluorobenzyl methacrylate-co-[2-[O-(1′-methyipropylideneamino)carboxyaminol]ethyl-methacrylate]), poly(styrene-co-{4-vinyl-(tetrahydro-2-pyranyl)benzoate}-co-pentafluorobenzyl methacrylate-co-[2-[O-(1′-methylpropylideneamino)carboxyamino]ethyl-methacrylate]), poly(styrene-co-{4-vinyl-(tetrahydro-2-pyranyl)benzoate}-co-pentafluorobenzyl methacrylate-co-[2-[1′-(3′, 5′-dimethylpyrazolyl)carboxyamino]ethyl-methacrylate]), poly(styrene-co-{4-vinyl-(tetrahydro-2-pyranyl)benzoate}-co-pentafluorobenzyl methacrylate-co-acrylonitrile-co-[2-[O-(1′-methyipropylideneamino)carboxyamino]ethyl-methacrylate]), poly(styrene-co-{4-vinyl-(tetrahydro-2-pyranyl) benzoate}-co-pentafluorobenzyl methacrylate-co-acrylonitrile-co-[2-[1′(3′, 5′-dimethylpyrazolyl) carboxyamino]ethyl-methacrylate]), poly(styrene-co-{4-vinyl-(tetrahydro-2-pyranyl)benzoate}-co-pentafluorobenzyl methacrylate-co-acrylonitrile-co-[2-[O-(1′-methylpropylideneamino)carboxyamino]ethyl-methacrylate]-co-allyltrimethylgermanium), poly(styrene-co-{4-vinyl-(tetrahydro-2-pyranyl)benzoate}-co-pentafluorobenzyl methacrylate-co-acrylonitrile-co-[2-[1′-(3′, 5′-dimetbylpyrazolyl)carboxyamino]ethyl-methacrylate]-co-allyltrimethylgermanium), poly(methyl methacrylate-co-{4-vinyl-(tetrahydro-2-pyranyl)benzoate}-co-pentafluorobenzyl methacrylate-co-[2-[O-(1′-methylpropylideneamino) carboxyamino]ethyl-methacrylate]), poly(methyl methacrylate-co-{4-vinyl-(tetrahydro-2-pyranyl)benzoate}-co-pentafluorobenzyl methacrylate-co-[2-[1′-(3′, 5′-dimethylpyrazolyl)carboxyamino]ethyl-methacrylate]), poly(styrene-co-{4-vinyl-(tetrahydro-2-pyranyl) benzoate}-co-pentafluorobenzyl methacrylate-co-(2,2,2-trifluoroethyl methacrylate)-co-[2-[O-(1′-methylpropylideneamino)carboxyamino]ethyl-methacrylate]), poly (styrene-co-{4-vinyl-(tetrahydro-2-pyranyl)benzoate}-co-pentafluorobenzyl methacrylate-co-(2,2,2-trifluoroethyl methacrylate)-co-[2-[1′-(3′, 5′-dimethylpyrazolyl) carboxyamino]ethyl-methacrylate]), and poly(styrene-co-4-(1-ethoxyethyl)styrene-co-{4-vinyl-(tetrahydro-2-pyranyl)benzoate}-co-4-trifluorobenzyl methacrylate-co-[2-[O-(1′-methylpropylideneamino) carboxyamino]ethyl-methacrylate]).

<Method for Producing Polymer Compound (A) and Polymer Compound (A-1)>

The polymer compound (A) can be produced, for example, by copolymerizing a monomer (a polymerizable monomer) serving as a raw material of a repeating unit represented by the formula (1), and at least one selected from the group consisting of a polymerizable monomer serving as a raw material of a repeating unit having an organic group represented by the formula (6) and a polymerizable monomer serving as a raw material of a repeating unit having an organic group represented by the formula (7), by using a photopolymerization initiator or a thermal polymerization initiator.

The polymer compound (A-1) can be produced by, for example, copolymerizing a polymerizable monomer serving as a raw material of a repeating unit represented by the formula (1), at least one selected from the group consisting of a polymerizable monomer serving as a raw material of a repeating unit having an organic group represented by the formula (2) and a polymerizable monomer serving as a raw material of a repeating unit having an organic group represented by the formula (3), and at least one selected from the group consisting of a polymerizable monomer serving as a raw material of a repeating unit having an organic group represented by the formula (6) and a polymerizable monomer serving as a raw material of a repeating unit having an organic group represented by the formula (7), by using a photopolymerization initiator or a thermal polymerization initiator.

In the production of the polymer compound (A) or the polymer compound (A-1), the blending molar ratio of a polymerizable monomer having an unsaturated double bond and a blocked isocyanato group or a blocked isothiocyanato group in a molecule is generally 1 mol % or more and 99 mol % or less, preferably 5 mol % or more and 60 mol % or less, and more preferably 10 mol % or more and 50 mol % or less, with respect to all monomers involved in the polymerization. By adjusting the blending molar ratio of the monomer to this range, a cross-linked structure is sufficiently formed inside a gate insulating layer, that is, a cured product obtained by curing the composition of the present invention, and the content of polar groups can be further reduced, which results in an improvement in solvent resistance.

The amount of use of the polymerizable monomer serving as a raw material of the repeating unit represented by the formula (1) is preferably adjusted so as to achieve an appropriate content of fluorine atoms in the polymer compound (A), depending on required properties. For example, the blending molar ratio of the polymerizable monomer serving as a raw material of the repeating unit represented by the formula (1) is generally 1 mol % or more and 99 mol % or less, preferably 5 mol % or more and 95 mol % or less, and more preferably 10 mol % or more and 90 mol % or less, with respect to all monomers involved in the polymerization.

Hereinafter, a polymerizable monomer used in a method for producing the polymer compound (A) and the polymer compound (A-1) will be described. It should be noted that the following “polymerizable monomer having a blocked isocyanato group or a blocked isothiocyanato group” is as described above.

Examples of the polymerizable monomer serving as a raw material of the repeating unit represented by the formula (1) may include 2,3,4,5,6-pentafluorobenzyl acrylate; 2,3,4,5,6-pentafluorobenzyl methacrylate, 2-fluorobenzyl acrylate, 2-fluorobenzyl methacrylate, 3-fluorobenzyl acrylate, 3-fluorobenzyl methacrylate, 4-fluorobenzyl acrylate, 4-fluorobenzyl methacrylate, 4-trifluoromethylbenzyl acrylate, and 4-trifluoromethylbenzyl methacrylate.

Examples of the polymerizable monomer serving as a raw material of the repeating unit having the organic group represented by the formula (2) may include 4-(methoxymethoxy) styrene, 4-(methoxyethoxymethoxy)styrene, 4-(1-ethoxyethoxy)styrene, 2-(methoxymethoxy)ethyl acrylate, 2-(methoxyethoxymethoxy)ethyl acrylate, 2-(1-ethoxyethoxy) ethyl acrylate, 2-(methoxymethoxy)ethyl methacrylate, 2-(methoxyethoxymethoxy)ethyl methacrylate, and 2-(1-ethoxyethoxy)ethyl methacrylate.

Examples of the polymerizable monomer serving as a raw material of the repeating unit having the organic group represented by the formula (3) may include 2-(methoxymethoxycarbonyl) styrene, 2-(methoxyethoxymethyloxycarbonyl) styrene, 2-(1-ethoxyethyloxycarbonyl)styrene, 2-(tetrahydopyranyloxycarbonyl)styrene, 3-(methoxymethoxycarbonyl)styrene, 3-(methoxyethoxymethyloxycarbonyl)styrene, 3-(1-ethoxyethyloxycarbonyl)styrene, 3-(tetrahydropyranyloxycarbonyl)styrene, 4-(methoxymethoxycarbonyl)styrene, 4-(methoxyethoxymethyloxycarbonyl)styrene, 4-(1-ethoxyethyloxycarbonyl)styrene, 4-(tetrahydropyranyloxycarbonyl)styrene, methoxymethyl acrylate, methoxyethoxymethyl acrylate, 1-ethoxyethyl acrylate, 2-acryloyloxyoxirane, 2-acryloyloxyoxetane, 2-acryloyloxy-2,3-dihydrofuran, 2-acryloyloxytetrahydrofuran, 2-acryloyloxy-3,4-dihydro-2H-pyran, 2-acryloyloxy-3,6-dihydro-2H-pyran, 2-acryloyloxy-tetrahydropyran, 2-acryloyloxy-2,3-dihydrooxepine, 2-acryloyloxy-2,3,4,5-tetrahydrooxepine, 2-acryloyloxy-2,3,6,7-tetrahydrooxepine, 2-acryloyloxy-hexahydrooxepine, 2-acryloyloxy-3,4-dihydro-2H-oxocin, 2-acryloyloxy-5,6-dihydro-2H-oxocin, 2-acryloyloxy-7,8-dihydro-2H-oxocin, 2-acryloyloxy-3,4,5,6-tetrahydro-2H-oxocin, 2-acryloyloxy-5,6,7,8-tetrahydro-2H-oxocin, 2-acryloyloxy-hexahydro-2H-oxocin, methoxymethyl-methacrylate, methoxyethoxymethyl-methacrylate, 1-ethoxyethyl-methacrylate, 2-methacryloyloxyoxirane, 2-methacryloyloxyoxetane, 2-methacryloyloxy-2,3-dihydrofuran, 2-methacryloyloxytetrahydrofuran, 2-methacryloyloxy-3,4-dihydro-2H-pyran, 2-methacryloyloxy-3,6-dihydro-2H-pyran, 2-methacryloyloxy-tetrahydropyran, 2-methacryloyloxy-2,3-dihydrooxepine, 2-methacryloyloxy-2,3,4,5-tetrahydrooxepine, 2-methacryloyloxy-2,3,6,7-tetrahydrooxepine, 2-methacryloyloxy-hexahydrooxepine, 2-methacryloyloxy-3,4-dihydro-2H-oxocin, 2-methacryloyloxy-5,6-dihydro-2H-oxocin, 2-methacryloyloxy-7,8-dihydro-2H-oxocin, 2-methacryloyloxy-3,4,5,6-tetrahydro-2H-oxocin, 2-methacryloyloxy-5,6,7,8-tetrahydro-2H-oxocin, and 2-methacryloyloxy-hexahydro-2H-oxocin.

The polymer compound (A) or the polymer compound (A-1) may be produced in such a manner that, in addition to the polymerizable monomer serving as a raw material of the repeating unit represented by the formula (1) and the polymerizable monomer having a blocked isocyanato group or a blocked isothiocyanato group, “another monomer” serving as a raw material of “another repeating unit” except the above-mentioned monomers is added in the production of the polymer compound (A). Here “another monomer” includes the polymerizable monomer serving as a raw material of the repeating unit having the organic group represented by the formula (2) and the polymerizable monomer serving as a raw material of the repeating unit having the organic group represented by the formula (3).

The blending molar ratio of the “another monomer” serving as a raw material of the “another repeating unit” is generally 0 mol % or more and 98 mol % or less, preferably 0 mol % or more and 85 mol % or less, and more preferably 0 mol % or more and 75 mol % or less, with respect to all monomers involved in the polymerization.

Examples of the “another monomer” may include acrylic acid esters and derivatives thereof, methacrylic acid esters and derivatives thereof, styrene and derivatives thereof, vinyl acetate and derivatives thereof, methacrylonitrile and derivatives thereof, acrylonitrile and derivatives thereof, organic carboxylic acid vinyl esters and derivatives thereof, organic carboxylic acid allyl esters and derivatives thereof, fumaric acid dialkyl esters and derivatives thereof, maleic acid dialkyl esters and derivatives thereof, itaconic acid dialkyl esters and derivatives thereof, organic carboxylic acid N-vinylamide derivatives, maleimides and derivatives thereof, terminal unsaturated hydrocarbons and derivatives thereof, and organic germanium derivatives.

The kind of the “another monomer” is appropriately selected according to properties required for a target to which the composition is applied, for example, properties required for a gate insulating layer. In the case where priority is given to excellent durability and reduced hysteresis, a monomer capable of forming a hard film having a high molecular density, such as styrene and styrene derivatives, is selected. As the “another monomer”, a monomer capable of providing plasticity, such as methacrylic acid esters and derivatives thereof and acrylic acid esters and derivatives thereof, is preferably employed because such a monomer can be used for a gate insulating layer, and allows the achievement of higher adhesiveness to a joint surface, such as the surface of a gate electrode or the surface of a substrate and allows the formation of a good interface.

Furthermore, the polymer compound (A) or the polymer compound (A-1) comprises a fluorine atom, and therefore, to improve the compatibility of the composition, the polymer compound (A) or the polymer compound (A-1) may be produced by further adding a monomer serving as a raw material of a repeating unit having a hydroxy group or a carboxy group so as to further comprise a repeating unit having a hydroxy group or a carboxy group.

Examples of the monomer serving as a raw material of a repeating unit having a hydroxy group or a carboxy group may include 4-hydroxybutyl acrylate, methacrylic acid, and vinylbenzoic acid.

For example, when the polymerizable monomer serving as a raw material of the repeating unit represented by the formula (1) and styrene or a styrene derivative serving as the “another monomer” are used in combination, the gate insulating layer has particularly high durability and reduced hysteresis.

As the acrylic esters and derivatives thereof serving as the “another monomer”, monofunctional acrylate and polyfunctional acrylate may be used, and examples thereof may include methyl acrylate, ethyl acrylate, n-propyl acrylate, isopropyl acrylate, n-butyl acrylate, isobutyl acrylate, sec-butyl acrylate, hexyl acrylate, octyl acrylate, 2-ethylhexyl acrylate, decyl acrylate, isobornyl acrylate, cyclohexyl acrylate, phenyl acrylate, benzyl acrylate, 2-hydroxyethyl acrylate, 2-hydroxypropyl acrylate, 3-hydroxypropyl acrylate, 2-hydroxybutyl acrylate, 2-hydroxyphenylethyl acrylate, 2-cyanoethyl acrylate, ethylene glycol diacrylate, propylene glycol diacrylate, 1,4-butanediol diacrylate, diethylene glycol diacrylate, triethylene glycol diacrylate, trimethylolpropane diacrylate, trimethylolpropane triacrylate, pentaerythritol pentaacrylate, N,N-dimethylacrylamide, N,N-diethylacrylamide, N-acryloylmorpholine, 2,2,2-trifluoroethyl acrylate, 2,2,3,3,3-pentafluoropropyl acrylate, 2-(perfluorobutyl)ethyl acrylate, 3-perfluorobutyl-2-hydroxypropyl acrylate, 2-(perfluorohexyl)ethyl acrylate, 3-perfluorohexyl-2-hydroxypropyl acrylate, 2-(perfluorooctyl)ethyl acrylate, 3-perfluorooctyl-2-hydroxypropyl acrylate, 2-(perfluorodecyl)ethyl acrylate, 2-(perfluoro-3-methylbutyl)ethyl acrylate, 3-(perfluoro-3-methylbutyl)-2-hydroxypropyl acrylate, 2-(perfluoro-5-methylhexyl)ethyl acrylate, 2-(perfluoro-3-methylbutyl)-2-hydroxypropyl acrylate, 3-(perfluoro-5-methylhexyl)-2-hydroxypropyl acrylate, 2-(perfluoro-7-methyloctyl)ethyl acrylate, 3-(perfluoro-7-methyloctyl)-2-hydroxypropyl acrylate, 1H,1H,3H-tetrafluoropropyl acrylate, 1H,1H,5H-octafluoropentyl acrylate, 1H,1H,7H-dodecafluoroheptyl acrylate, 1H,1H,9H-hexadecafluorononyl acrylate, 1H-1-(trifluoromethyl)trifluoroethyl acrylate, and 1H,1H,3H-hexafluorobutyl acrylate.

As the methacrylic acid esters and derivatives thereof serving as the “another monomer”, monofunctional methacrylate and polyfunctional methacrylate may be used. Examples of the methacrylic acid esters and derivatives thereof may include methyl methacrylate, ethyl methacrylate, n-propyl methacrylate, isopropyl methacrylate, n butyl methacrylate, isobutyl methacrylate, sec-butyl methacrylate, hexyl methacrylate, octyl methacrylate, 2-ethylhexyl methacrylate, decyl methacrylate, isobornyl methacrylate, cyclohexyl methacrylate, phenyl methacrylate, benzyl methacrylate, 2-hydroxyethyl methacrylate, 2-hydroxypropyl methacrylate, 3-hydroxypropyl methacrylate, 2-hydroxybutyl methacrylate, 2-hydroxyphenylethyl methacrylate, 2-cyanoethyl methacrylate, ethylene glycol dimethacrylate, propylene glycol dimethacrylate, 1,4-butanediol dimethacrylate, diethylene glycol dimethacrylate, triethylene glycol dimethacrylate, trimethylolpropane dimethacrylate, trimethylolpropane trimethacrylate, pentaerythritol pentamethacrylate, N,N-dimethylmethacrylamide, N,N-diethylmethacrylamide, N-acryloylmorpholine, 2,2,2-trifluoroethyl methacrylate, 2,2,3,3,3-pentafluoropropyl methacrylate, 2-(perfluorobutyl)ethyl methacrylate, 3-perfluorobutyl-2-hydroxypropyl methacrylate, 2-(perfluorohexyl)ethyl methacrylate, 3-perfluorohexyl-2-hydroxypropyl methacrylate, 2-(perfluorooctyl)ethyl methacrylate, 3-perfluorooctyl-2-hydroxypropyl methacrylate, 2-(perfluorodecyl)ethyl methacrylate, 2-(perfluoro-3-methylbutyl)ethyl methacrylate, 3-(perfluoro-3-methylbutyl)-2-hydroxypropyl methacrylate, 2-(perfluoro-5-methylhexyl)ethyl methacrylate, 2-(perfluoro-3-methylbutyl)-2-hydroxypropyl methacrylate, 3-(perfluoro-5-methylhexyl)-2-hydroxypropyl methacrylate, 2-(perfluoro-7-methyloctyl)ethyl methacrylate, 3-(perfluoro-7-methyloctyl)-2-hydroxypropyl methacrylate, 1H,1H,3H-tetrafluoropropyl methacrylate, 1H,1H,5H-octafluoropentyl methacrylate, 1H,1H,7H-dodecafluoroheptyl methacrylate, 1H,1H,9H-hexadecafluorononyl methacrylate, 1H-1-(trifluoromethyl)trifluoroethyl methacrylate, 1H,1H,3H-hexafluorobutyl methacrylate, and 3,3,4,4,5,5,6,6,7,7,8,8,9,9,10,10,10-heptadecafluorodecyl methacrylate.

Examples of styrene and derivatives thereof serving as the “another monomer” may include styrene, 2,4-dimethyl-α-methylstyrene, o-methylstyrene, m-methylstyrene, p-methylstyrene, 2,4-dimethylstyrene, 2,5-dimethylstyrene, 2,6-dimethylstyrene, 3,4-dimethylstyrene, 3,5-dimethylstyrene, 2,4,6-trimethylstyrene, 2,4,5-trimethylstyrene, pentamethylstyrene, o-ethylstyrene, m-ethylstyrene, p-ethylstyrene, o-chlorostyrene, m-chlorostyrene, p-chlorostyrene, o-bromostyrene, m-bromostyrene, p-bromostyrene, o-methoxystyrene, m-methoxystyrene, p-methoxystyrene, o-hydroxystyrene, m-hydroxystyrene, p-hydroxystyrene, 2-vinylbiphenyl, 3-vinylbiphenyl, 4-vinylbiphenyl, 1-vinylnaphthalene, 2-vinylnaphthalene, 4-vinyl-p-terphenyl, 1-vinylanthracene, α-methylstyrene, o-isopropenyltoluene, m-isopropenyltoluene, p-isopropenyltoluene, 2,4-dimethyl-α-methylstyrene, 2,3-dimethyl-α-methylstyrene, 3,5-dimethyl-α-methylstyrene, p-isopropyl-α-methylstyrene, α-ethylstyrene, α-chloroctyrene, divinylbenzene, divinylbiphenyl, diisopropylbenzene, 4-aminostyrene, and 4-[(1-ethoxy)ethoxy]styrene.

Acrylnitrile and derivatives thereof serving as the “another monomer” may be acrylonitrile. Examples of methacrylnitrile and derivatives thereof serving as the “another monomer” may include methacrylonitrile.

Examples of the organic carboxylic acid vinyl esters and derivatives thereof serving as the “another monomer” may include vinyl acetate, vinyl propionate, vinyl butyrate, vinyl benzoate, divinyl adipate, and 4-vinylbenzoic acid tetrahydropyranyl esters.

Examples of the organic carboxylic acid allyl esters and derivatives thereof serving as the “another monomer” may include allyl acetate, allyl benzoate, diallyl adipate, diallyl terephthalate, diallyl isophthalate, and diallyl phthalate.

Examples of the fumaric acid dialkyl esters and derivatives thereof serving as the “another monomer” may include dimethyl fumarate, diethyl fumarate, diisopropyl fumarate, di-sec-butyl fumarate, diisobutyl fumarate, di-n-butyl fumarate, di-2-ethylhexyl fumarate, and dibenzyl fumarate.

The maleic acid dialkyl esters and derivatives thereof serving as the “another monomer” may be dimethyl maleate, diethyl maleate, diisopropyl maleate, di-sec-butyl maleate, diisobutyl maleate, di-n-butyl maleate, di-2-ethylhexyl maleate, or dibenzyl maleate.

Examples of the itaconic acid dialkyl esters and derivatives thereof serving as the “another monomer” may include dimethyl itaconate, diethyl itaconate, diisopropyl itaconate, di-sec-butyl itaconate, di-isobutyl itaconate, di-n-butyl itaconate, di-2-ethylhexyl itaconate, and dibenzyl itaconate.

Examples of the organic carboxylic acid N-vinylamide derivatives serving as the “another monomer” may include N-methyl-N-vinylacetamide.

Examples of maleimide and derivatives thereof serving as the “another monomer” may include N-phenylmaleimide and N-cyclohexylmaleimide.

Examples of the terminal unsaturated hydrocarbons and derivatives thereof serving as the “another monomer” may include 1-butene, 1-pentene, 1-hexene, 1-octene, vinylcyclohexane, vinyl chloride, and allyl alcohol.

Examples of the organic germanium derivatives serving as the “another monomer” may include allyltrimethylgermanium, allyltriethylgermanium, allyltributylgermanium, trimethylvinylgermanium, and triethylvinylgermanium.

Among these “another monomer”, acrylic acid alkyl esters, methacrylic acid alkyl esters, styrene, acrylonitrile, methacrylonitrile, and allyltrimethylgermanium are preferred.

Examples of a photopolymerization initiator to be used for the production of the polymer compound (A) may include carbonyl compounds, such as acetophenone, 2,2-dimethoxy-2-phenylacetophenone, 2,2-diethoxyacetophenone, 4-isopropyl-2-hydroxy-2-methylpropiophenone, 2-hydroxy-2-methylpropiophenone, 4,4′-bis(diethylamino)benzophenone, benzophenone, methyl(o-benzoyl)benzoate, 1-phenyl-1,2-propanedione-2-(o-ethoxycarbonyl)oxime, 1-phenyl-1,2-propanedione-2-(o-benzoyl)oxime, benzoin, benzoin methyl ether, benzoin ethyl ether, benzoin isopropyl ether, benzoin isobutyl ether, benzoin octyl ether, benzil, benzyl dimethyl ketal, benzyl diethyl ketal, and diacetyl; derivatives of anthraquinone and derivatives of thioxanthone, such as methylanthraquinone, chloroanthraquinone, chlorothioxanthone, 2-methylthioxanthone, and 2-isopropylthioxanthone; and sulfur compounds, such as diphenyldisulfide and dithiocarbamate.

A thermal polymerization initiator to be used for the production of the polymer compound may be any initiator for radical polymerization. Examples of the thermal polymerization initiator may include azo compounds, such as 2,2′-azobisisobutyronitrile, 2,2′-azobisisovaleronitrile, 2,2′-azobis(2,4-dimethylvaleronitrile), 4,4′-azobis(4-cyanovaleric acid), 1,1′-azobis(cyclohexanecarbonitrile), 2,2′-azobis(2-methylpropane), and 2,2′-azobis(2-methylpropionamidine)dihydrochloride; ketone peroxides, such as methyl ethyl ketone peroxide, methyl isobutyl ketone peroxide, cyclohexanone peroxide, and acetylacetone peroxide; diacyl peroxides, such as isobutyl peroxide, benzoyl peroxide, 2,4-dichlorobenzoyl peroxide, o-methylbenzoyl peroxide, lauroyl peroxide, and p-chlorobenzoyl peroxide; hydroperoxides, such as 2,4,4-trimethylpentyl-2-hydroperoxide, diisopropylbenzene peroxide, cumene hydroperoxide, and tert-butyl peroxide; dialkyl peroxides, such as dicumyl peroxide, tert-butylcumyl peroxide, di-tert-butyl peroxide, and tris(tert-butylperoxy)triazine; peroxyketals, such as 1,1-di-tert-butylperoxycyclohexane and 2,2-di(tert-butylperoxy)butane; alkyl peresters, such as tert-butyl peroxypivalate, tert-butyl peroxy-2-ethylhexanoate, tert-butyl peroxyisobutylate, di-tert-butyl peroxyhexahydroterephthalate, di-tert-butyl peroxyazelate, tert-butyl peroxy-3,5,5-trimethylhexanoate, tert-butyl peroxyacetate, tert-butyl peroxybenzoate, and di-tert-butyl peroxytrimethyladipate; and percarbonates, such as diisopropyl peroxydicarbonate, di-sec-butyl peroxydicarbonate, and tert-butyl peroxyisopropylcarbonate.

Composition

The composition of the present invention comprises the already-explained polymer compound (A). The composition of the present invention preferably comprises the already-explained polymer compound (A-1).

<Compound (B)>

The composition of the present invention may further comprise at least one compound (B) selected from the group consisting of a low molecular compound having at least two active hydrogens and a polymer compound having at least two active hydrogens.

The active hydrogen that the compound (B) has may be typically hydrogen atoms comprised in an amino group, a hydroxy group, or a mercapto group. As the active hydrogen, a hydrogen atom comprised in a hydroxy group in a phenolic hydroxy group and a hydrogen atom comprised in an amino group in an aromatic amino group that are capable of sufficiently promoting a reaction with the above-mentioned reactive functional groups, particularly, an isocyanato group and an isothiocyanato group are preferred.

Specific examples of the compound (B) serving as the low molecular compound having at least two active hydrogens may include a compound having a structure in which a group having two or more active hydrogens is bonded to a low molecular (monomer) structure. Examples of the low molecular structure may include an alkyl structure and a benzene ring structure. Specific examples of the compound (B) serving as the low molecular compound having at least two active hydrogens may include low molecular compounds, such as an amine compound, an alcohol compound, a phenolic compound, and a thiol compound.

Examples of the amine compound serving as the compound (B) may include ethylenediamine, propylenediamine, hexamethylenediamine, N,N,N′,N′-tetraaminoethylethylenediamine, o-phenylenediamine, meta-phenylenediamine, p-phenylenediamine, N,N′-diphenyl-p-phenylenediamine, melamine, 2,4,6-triaminopyrimidine, 1,5,9-triazacyclododecane, 1,3-bis(3-aminopropyl)tetramethyldisiloxane, 1,4-bis(3-aminopropyldimethylsilyl)benzene, 3-(2-aminoethylaminopropyl)tris(trimethylsiloxy)silane, 1,3-bis(3′-aminophenoxy)benzene, 2,2-ditrifluoromethylbenzidine, 1,3-bis(3-aminopropyl)-1,1,3,3-tetramethyldisiloxane, 1,4-bis(3-aminopropyldimethylsilyl)benzene, and 3-(2-aminoethylaminopropyl)tris(trimethylsiloxy)silane.

Examples of the alcohol compound serving as the compound (B) may include ethylene glycol, 1,2-dihydroxypropane, glycerol, and 1,4-dimethanol benzene. The phenolic compound may be 1,2-dihydroxybenzene, 1,3-dihydroxybenzene, 1,4-dihydroxybenzene, 1,2-dihydroxynaphthalene, resorcin, fluoroglycerol, 2,3,4-trihydroxybenzaldehyde, 3,4,5-trihydroxybenzamide, or di(4-hydroxy-3-nitrophenyl)ether.

Examples of the thiol compound serving as the compound (B) may include ethylenedithiol and p-phenylenedithiol.

As the polymer compound having at least two active hydrogens serving as the compound (B), the active hydrogens may be bonded directly to a main chain constituting the polymer compound, or may be bonded thereto via a predetermined group. Alternatively, the active hydrogens may be comprised in repeating units constituting the polymer compound. In the case where the active hydrogens are comprised in the repeating units, the active hydrogens may be comprised in each of the repeating units, or may be comprised in only some of the repeating units. Furthermore, the active hydrogens may be bonded only to a terminal of the polymer compound.

Specific examples of the polymer compound serving as the compound (B) may include a compound having a structure in which a group having two or more active hydrogens is bonded to a polymer (polymeride) structure. The polymer compound serving as the compound (B) can be obtained by forming a polymer in such a manner that a monomer compound (a monomer) having a group comprising active hydrogens and an unsaturated bond such as a double bond in a molecule is singly polymerized or is copolymerized with another copolymerizable compound. In the polymerization, a photopolymerization initiator or a thermal polymerization initiator may he used. Here, the polymerizable monomer, the photopolymerization initiator, and the thermal polymerization initiator that have been already-explained in the description of the polymer compound (A) may be used as a polymerizable monomer, a photopolymerization initiator, and a thermal polymerization initiator.

Examples of the monomer having a group comprising active hydrogens and an unsaturated bond in a molecule may include aminostyrene, hydroxystyrene, vinylbenzyl alcohol, aminoethyl methacrylate, and ethylene glycol monovinyl ether.

As the polymer compound serving as the compound (B), a novolak resin obtained by condensation of a phenolic compound and formaldehyde under the presence of an acid catalyst is also preferred. Furthermore, as the polymer compound, a polysilsesquioxane compound obtained by condensation of an organosilicon compound under the presence of an acid catalyst is also preferred. Examples of the polysilsesquioxane compound may include poly{dimethyl-2-(4′-hydroxyphenyl)ethylsilylsilsesquioxane}.

The polymer compound having two or more groups each comprising active hydrogens in a molecule, serving as the compound (B), has a polystyrene-equivalent weight-average molecular weight of preferably 1,000 to 1,000,000, and more preferably 3,000 to 500,000. When the weight-average molecular weight of the polymer compound is within such range, an insulating layer that is a cured product obtained by curing the composition of the present invention allows achievement of excellent flatness and uniformity.

A composition further the compound (B) in addition to the polymer compound (A) or the polymer compound (A-1) is suitable as a composition particularly for a gate insulating layer of an organic thin film transistor. The mixing ratio of the polymer compound (A) or the polymer compound (A-1) to the compound (B) is adjusted so that the molar ratio of a functional group (the second functional group) of the polymer compound (A) or the polymer compounds (A-1) to react with active hydrogens to a group comprising the active hydrogens in the compound (B) is preferably 60/100 to 150/100, more preferably 70/100 to 120/100, and still more preferably 90/100 to 110/100. From the viewpoint of sufficiently reducing the hysteresis, this molar ratio is preferably 60/100 or more, and from the viewpoint of reducing the absolute value of threshold voltage by preventing an excess of functional groups that react to the active hydrogens, this molar ratio is preferably 150/100 or less.

The use of the polymer compound (A-1) allows a preferred composition for a gate insulating layer to be obtained without mixing-in the compound (B). R^{A} and R^{B} in the formula (2) and the formula (3) are decomposed and dissociated by, for example, heat treatment, whereby a hydroxyl group is generated, and the hydroxyl group reacts with a functional group of the polymer compound (A-1), the functional group reacting with active hydrogens, whereby a cross-linked structure is formed.

The molar ratio of a repeating unit having the functional group of the polymer compound (A-1), the functional group reacting with active hydrogens, to a repeating unit having an organic group represented by the formula (2) or the formula (3) is adjusted to preferably 60/100 to 150/100, more preferably 70/100 to 120/100, and still more preferably 90/100 to 110/100.

When the polymer compound (A-1) and the compound (B) are mixed to obtain a composition for a gate insulating layer, the molar ratio of the functional group of the polymer compound (A-1), the functional group reacting with active hydrogens, to the total amount of an organic group represented by the formula (2) or the formula (3) and the group having active hydrogens in the compound (B) is adjusted to preferably 60/100 to 150/100, more preferably 70/100 to 120/100, and still more preferably 90/100 to 110/100.

<Polymer Compound (C)>

The composition of the present invention may further comprise at least one polymer compound (C) that does not in comprise a repeating unit represented by the formula (1) and comprises a repeating unit having a blocked isocyanato group or a blocked isothiocyanato group. The composition of the present invention that comprises the polymer compound (C) allows achievement of the effect of easily controlling an affinity for an organic semiconductor layer.

The polymer compound (C) can be produced by using the already-explained polymerizable monomer serving as a material of the repeating unit having a blocked isocyanato group or a blocked isothiocyanato group.

The composition of the present invention may comprise two or more polymer compounds (A), for example, two or more polymer compounds (A) each comprising “another repeating unit” other than a repeating unit represented by the formula (1), a repeating unit having a blocked isocyanato group, and the repeating unit having a blocked isocyanato group, the other repeating units being different from each other.

The composition of the present invention may comprise at least two or more polymer compounds selected from the group consisting of the polymer compound (A) and the polymer compound (A-1).

The content of the polymer compound (A) in the composition of the present invention is generally 1% by mass to 50% by mass with respect to the entirety of the composition.

The composition of the present invention may comprise a solvent for mixing or viscosity control and an additive that is generally used in combination with a cross-linking agent to cross-link a polymer compound.

Examples of the solvent to be used may include ether solvents such as tetrahydrofuran and dibutyl ether, aliphatic hydrocarbon solvents such as hexane, cycloaliphatic hydrocarbon solvents such as cyclohexane, unsaturated hydrocarbon solvents such as pentene, aromatic hydrocarbon solvents such as xylene, ketone solvents such as acetone, acetate solvents such as butyl acetate, alcohol solvents such as isopropyl alcohol, halide solvents such as chloroform, and mixed solvents thereof. Furthermore, as the additive, a catalyst for accelerating a cross-linking reaction, a leveling agent, and a viscosity controlling agent can be used. The amount of the additive used is generally 0.1 parts by weight to 10 parts by weight, based on 100 parts by weight of the polymer compound (A) comprised in the composition.

Cured Film of Composition

A cured film of the composition of the present invention can be formed by a formation method comprising the steps of applying the above-described composition of the present invention to, for example, a surface of a base material serving as a formation target to form a coating layer, and curing the coating layer.

The method for forming the cured film of the composition is such that the composition of the present invention is soaked with, for example, a solvent (an organic solvent), if necessary, to prepare a coating solution for film formation; the prepared coating solution is applied onto a surface of a base material; and the formed coating layer is cured to obtain a cured film of the composition of the present invention.

The organic solvent usable for the preparation of the coating solution is not limited to a particular one and only required to be capable of dissolving components, such as the polymer compound and a cross linking agent, comprised in the composition, and preferably has a boiling point of 100° C. to 200° C. under normal pressure. Preferred examples of the organic solvent may include 2-heptanone and propylene glycol monomethyl ether acetate. The coating solution for film formation can comprise, for example, a leveling agent, a surfactant, and a curing catalyst, as necessary.

In the case where the organic solvent is used, the amount of the organic solvent comprised in the coating solution is preferably 30% by mass to 95% by mass, and still more preferably 50% by mass to 95% by mass with respect to the entirety of the coating solution.

The coating solution for film formation can be applied onto a base material by a conventionally known coating method, such as spin coating method, die coating method, screen printing method, or inkjet printing method.

An object of the step of drying the coating layer in the film formation method is to remove the solvent in the coating layer formed on the base material by the coating method. An object of the curing step is to promote a cross-linking reaction with a reactive functional group comprised in the polymer compound in the coating layer, and thereby forming a film as a cured film of the composition.

The curing step of the composition of the present invention comprises, as a first stage, dissociating a protective group derived from a blocking agent from a blocked isocyanato group and/or a blocked isothiocyanato group and thereby producing an isocyanato group and/or an isothiocyanato group that are capable of reacting with active hydrogen; and, as a second stage, reacting the generated isocyanato group and/or the generated isothiocyanato group with a hydroxy group and/or a carboxy group that comprise active hydrogen.

When the first stage is compared with the second stage, the reaction rate of the reaction in the first stage is lower than the reaction rate of the reaction in the second stage. Hence, once the first stage is caused to proceed, the second stage automatically proceeds. Therefore, in order to cure the composition of the present invention, it is only required that the first stage is caused to proceed.

In order to cause the first stage to proceed, for example, electromagnetic wave or heat is caused to act on the coating layer. In order to cause electromagnetic wave or heat to act on the coating layer, specifically, irradiating electromagnetic wave to the coating layer, and baking the coating layer are comprised.

The irradiation with electromagnetic wave can be performed by using, for example, an exposure apparatus conventionally used for manufacturing semiconductor devices or a UV lamp used for curing UV-curable resins.

The baking can be performed by, for example, heat-treatment at a temperature of 80° C. to 300° C., preferably 120° C. to 250° C. for 5 minutes to 2 hours, preferably about 10 minutes to about 1 hour. Electromagnetic wave irradiation conditions and baking conditions to dissociate a protective group derived from a blocking agent from a blocked isocyanato group and/or a blocked isothiocyanato group can be appropriately determined in accordance with the kinds and amount of the blocked isocyanato group and/or the blocked isothiocyanato group.

Electronic Device

An electronic device comprising the “cured film of the composition” of the present invention will be described. The above-explained cured film of the composition of the present invention is applicable to various electronic devices, such as an organic thin film transistor, an organic LED, and a sensor.

As described above, as the electronic device comprising the “cured film of the composition” of the present invention, an organic thin film transistor is preferred. The “cured film of the composition” of the present invention is preferably comprised as a gate insulating layer of an organic thin film transistor.

The use of the “cured film of the composition” in particular as a gate insulating layer of an organic thin film transistor allows the carrier mobility of the organic thin film transistor to be effectively improved.

The “cured film of the composition” of the present invention has excellent insulating properties, excellent sealing properties, excellent adhesiveness, and excellent solvent resistance, and therefore, can be also used as a protective layer, such as an overcoat layer or an undercoat layer of an organic thin film transistor.

For example, in addition to the cured film of the composition of the present invention serving as the gate insulating layer, the organic thin film transistor of the present invention may further comprise a cured film of the composition of the present invention as an overcoat layer.

Hereinafter, the organic thin film transistor to which the “cured film of the composition” of the present invention is suitably applicable will be described.

<Organic Thin Film Transistor>

The organic thin film transistor of the present invention comprises the above-explained cured film of the composition. Hereinafter, embodiments of the organic thin film transistor to which the “cured film of the composition” of the present invention is suitably applicable will be described with reference to the drawings.

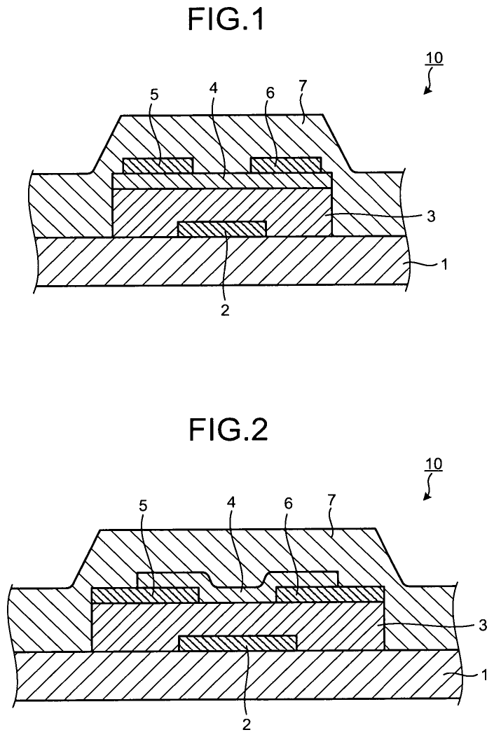

FIG. 1 is a schematic diagram illustrating a structure of a bottom-gate top-contact type organic thin film transistor according to a first embodiment of the present invention.

As illustrated in FIG. 1, an organic thin film transistor 10 of the first embodiment comprises a substrate 1, a gate electrode 2 provided so as to be joined to a main surface of the substrate 1, a gate insulating layer 3 provided in the substrate 1 so as to cover the gate electrode 2, an organic semiconductor layer 4 provided so as to be joined to the gate insulating layer 3 and cover just above the gate electrode 2, a source electrode 5 and a drain electrode 6 that are provided so as to be joined to the organic semiconductor layer 4, sandwich a channel area, and be spaced from each other such that the channel area overlaps the gate electrode 2 when viewed from the thickness direction of the substrate 1 (at a planar view), and an overcoat layer 7 provided so as to cover the gate electrode 2, the gate insulating layer 3, the organic semiconductor layer 4, the source electrode 5, and the drain electrode 6, which are provided in the substrate 1.

FIG. 2 is a schematic diagram illustrating a structure of a bottom-gate bottom-contact type organic thin film transistor according to a second embodiment of the present invention.

As illustrated in FIG. 2, an organic thin film transistor 10 of the second embodiment comprises a substrate 1, a gate electrode 2 provided so as to be joined to a main surface of the substrate 1, a gate insulating layer 3 provided in the substrate 1 so as to cover the gate electrode 2, a source electrode 5 and a drain electrode 6 that are provided so as to be joined to the gate insulating layer 3, sandwich a channel area, and be spaced from each other such that the channel area overlaps the gate electrode 2 when viewed from the thickness direction of the substrate 1 (at a planar view), an organic semiconductor layer 4 provided so as to extend across the source electrode 5 and the drain electrode 6 and cover a part of the gate insulating layer 3 comprising a part of the source electrode 5, a part of the drain electrode 6, and the channel area, and an overcoat layer 7 provided so as to cover the gate electrode 2, the gate insulating layer 3, the organic semiconductor layer 4, the source electrode 5, and the drain electrode 6, which are provided in the substrate 1.

<Method for manufacturing Organic Thin Film Transistor>

The bottom-gate top-contact type organic thin film transistor 10 of the first embodiment can be manufactured, for example, by forming the gate electrode 2 on the main surface of the substrate 1, forming the gate insulating layer 3 on the surface of the substrate 1 (base material) provided with the gate electrode 2 so as to cover the gate electrode 2; forming the organic semiconductor layer 4 on the gate insulating layer 3; forming the source electrode 5 and the drain electrode 6 so as to be joined to the organic semiconductor layer 4; and furthermore, forming the overcoat layer 7, if necessary, so as to cover the gate electrode 2, the gate insulating layer 3, the organic semiconductor layer 4, the source electrode 5, and the drain electrode 6, which are provided in the substrate 1.

The bottom-gate bottom-contact type organic thin film transistor 10 of the second embodiment can be manufactured, for example, by forming the gate electrode 2 on the main surface of the substrate 1, forming the gate insulating layer 3 on the surface of the substrate 1 (base material) provided with the gate electrode 2 so as to cover the gate electrode 2; forming the source electrode 5 and the drain electrode 6 on the gate insulating layer 3; forming the organic semiconductor layer 4 so as to extend across the source electrode 5 and the drain electrode 6 and cover a part of the gate insulating layer 3 comprising a part of the source electrode 5, a part of the drain electrode 6, and the channel area; and furthermore, forming the overcoat layer 7, if necessary, so as to cover the gate electrode 2, the gate insulating layer 3, the organic semiconductor layer 4, the source electrode 5, and the drain electrode 6, which are provided in the substrate 1.

A formation method (formation process) for the gate insulating layer 3 of the organic thin film transistor 10 of the present invention is the same as the above-explained formation method for the “cured film of the composition”.

The formation method (formation process) for the gate insulating layer 3 comprises the steps of applying the composition of the present invention onto a surface of a base material to form a coating layer, and curing the coating layer.

The formation process for the gate insulating layer 3 can be implemented by soaking the composition of the present invention with, for example, a solvent (an organic solvent), if necessary, to prepare a coating solution for the formation of the gate insulating layer 3; applying the prepared coating solution onto a substrate 1 provided with the gate electrode 2; and drying and curing the formed coating layer to form a cured film of the composition.

The contact angle of the gate insulating layer 3 with pure water can be appropriately adjusted by increasing or decreasing the hydrophilicity of a surface of the gate insulating layer 3, in consideration of the amount of a fluorine atom, a hydrophobic functional group, and a hydrophilic functional group that are comprised in the polymer compound in the composition. The hydrophilicity of the surface of the gate insulating layer 3 can be increased or decreased by adjusting components of atmosphere in which heat-treatment is to be carried out. For example, when the drying step and the curing step (heating or baking) performed to form the gate insulating layer 3 are implemented in an oxygen-containing atmosphere, the hydrophilicity of the surface of the gate insulating layer 3 is increased. In contrast, when the drying step and the curing step are implemented in an inert gas atmosphere, the hydrophilicity of the surface of the gate insulating layer 3 is decreased. In the case where the steps are implemented in an oxygen-containing atmosphere, when a temperature is increased, the hydrophilicity of the surface of the gate insulating layer 3 is further increased.

On a surface of the gate insulating layer 3 on the organic semiconductor layer 4 side, a self-assembled monomolecular layer may be formed. The self-assembled monomolecular layer can be formed by, for example, treating the gate insulating layer 3 with a solution in which 1% to 10% by weight of an alkylchlorosilane compound or an alkylalkoxysilane compound is dissolved in an organic solvent.

Examples of the alkylchlorosilane compound to be used for forming the self-assembled monomolecular layer may include methyltrichlorosilane, ethyltrichlorosilane, butyltrichlorosilane, decyltrichlorosilane, and octadecyltrichlorosilane.

Examples of the alkylalkoxysilane compound to be used for forming the self-assembled monomolecular layer may include methyltrimethoxysilane, ethyltrimethoxysilane, butyltrimethoxysilane, decyltrimethoxysilane, and octadecyltrimethoxysilane.

The substrate 1, the gate electrode 2, the source electrode 5, the drain electrode 6, and the organic semiconductor layer 4 can be constituted using materials and methods that are generally used in a conventionally known method for manufacturing organic thin film transistors. For example, a resin substrate or a resin film, a plastic substrate or a plastic film, a glass substrate, or a silicon substrate is used as the substrate 1. Examples of materials of the gate electrode 2, the source electrode 5, and the drain electrode 6 may include chromium, gold, silver, and aluminum. The gate electrode 2, the source electrode 5, and the drain electrode 6 can be formed by a known method, such as a vacuum deposition method, a sputtering method, or an inkjet printing method.

A n-conjugated polymer is used as an organic semiconductor compound serving as a material of the organic semiconductor layer 4. Examples of the n-conjugated polymer to be used may include polypyrroles, polythiophenes, polyanilines, polyallylamines, fluorenes, polycarbazoles, polyindoles, and poly(p-phenylenevinylene)s.

As the organic semiconductor compound serving as a material of the organic semiconductor layer 4, a low molecular compound having solubility into an organic solvent can be used. Examples of the low molecular compound may include derivatives of polycyclic aromatics such as pentacene, phthalocyanine derivatives, perylene derivatives, tetrathiafulvalene derivatives, tetracyanoquinodimethane derivatives, fullerenes, and carbon nanotubes. Specific examples of the low molecular compound may include a condensate of 9,9-di-n-octylfluorene-2,7-di(ethyleneboronate) and 5,5′-dibromo-2,2′-bithiophene.

The formation process for the organic semiconductor layer 4 is implemented, for example, in such a manner that, for example, a solvent is added if necessary to an organic semiconductor compound to prepare a coating solution for the formation of the organic semiconductor layer 4; the prepared coating solution is applied to the gate insulating layer 3, the source electrode 5, and the drain electrode 6; and the resultant coating layer is dried. In the present invention, the polymer compound constituting the gate insulating layer 3 has a phenyl moiety or a carbonyl moiety and has an affinity for an organic semiconductor compound. Therefore, through the above-described application step and drying step, a uniform and flat interface can be formed between the organic semiconductor layer 4 and the gate insulating layer 3.

The solvent usable for the formation process for the organic semiconductor layer 4 is not limited to a particular one, but is only required to be capable of dissolving or distributing an organic semiconductor compound therein. As such solvent, a solvent having a boiling point of 50° C. to 200° C. under normal pressure is preferable. Examples of the solvent may include chloroform, toluene, anisole, 2-heptanone, and propylene glycol monomethyl ether acetate. The coating solution for the formation of the organic semiconductor layer 4 can be applied onto the gate insulating layer 3 by a known coating method, such as spin coating method, die coating method, screen printing method, or inkjet printing method, in the same manner as the above-explained coating solution for the formation of the insulating layer 3.

In the same manner as in the above-explained formation process for the gate insulating layer 3, the overcoat layer 7 (protective layer) can be formed using the above-explained composition for insulating layers of the present invention.

Furthermore, the under coat layer, not illustrated, can be formed in the same manner as in the case of the overcoat layer 7.

<Use of Organic Thin Film Transistor>

Using an organic thin film transistor manufactured using the composition of the present invention, a display member comprising the organic thin film transistor can be manufactured.

Furthermore, using the display member comprising the organic thin film transistor, a display comprising the display member can be manufactured.

The organic thin film transistor manufactured using the composition of the present invention can be also used for an organic field effect transistor (OFET) sensor. The OFET sensor is a sensor that uses an organic thin film transistor (organic field effect transistor: OFET) as a signal conversion element configured to convert an input signal into an electric signal and output the electric signal, and that is provided with a sensitivity function or a selectivity function in the structure of any of an electrode, an insulating layer, and an organic semiconductor layer. Examples of the OFET sensor may include a biosensor, a gas sensor, an ion sensor, and a humidity sensor.

For example, a biosensor comprises the organic thin film transistor having the above-described configuration. The organic thin film transistor has, in the channel area and/or the gate insulating layer, a probe (sensitive area) that interacts specifically with a target substance. When the concentration of the target substance changes, the electrical properties of the probe change, and thus the organic thin film transistor can function as a biosensor.

Examples of a method for detecting a target substance in a test sample may include a method in which a biomolecule, such as nucleic acid or protein, or an artificially synthesized functional group is fixed to a surface of a solid phase carrier, and the resultant is used as a probe.

In this method, a target substance is caught with the solid phase carrier probe by making use of a specific affinity between substances or functional groups, such as an interaction of nucleic acid chains having complementary sequence, an antigen-antibody reaction, an enzyme-substrate reaction, or a receptor-ligand interaction. Therefore, a substance or a functional group that has a specific affinity for a target substance is selected as the probe.

The probe is fixed to a surface of the solid phase carrier by a method depending on the kind of the selected probe and the kind of the solid phase carrier. Furthermore, the probe may be produced on the surface of the solid phase carrier by synthesis. Specifically, the probe can be produced by, for example, synthesis by a nucleic acid elongation reaction. In any of the cases, the probe fixed to the surface of the solid phase carrier is made into contact with a test sample, and treated under appropriate conditions, whereby a probe-target substance composite is formed on the surface of the solid phase carrier. Alternatively, the channel area and/or the gate insulating layer of the organic thin film transistor may function as the probe.

A gas sensor comprises the organic thin film transistor having the above-described configuration. In this case, in the organic thin film transistor, the channel area and/or the gate insulating layer function as a gas sensing unit. When gas to be detected comes into contact with the gas sensing unit, electric characteristics (for example, conductivity and dielectric constant) of the gas sensing unit are changed, and thus the organic thin film transistor can function as a gas sensor.

Examples of the gas to be detected may include electron acceptor gas and electron donor gas. Examples of the electron acceptor gas may include halogen gas such as F₂ and Cl₂, nitrogen oxide gas, sulfur oxide gas, and organic acid gas such as acetic acid. Examples of the electron donor gas may include ammonia gas, amine gas such as aniline gas, carbon monoxide gas, and hydrogen gas.

The organic thin film transistor manufactured using the composition of the present invention can be used for manufacturing of a pressure sensor. The pressure sensor comprises the organic thin film transistor having the above-described configuration. In this case, in the organic thin film transistor, the channel area and/or the gate insulating layer function as a pressure sensing unit. When a stress is applied to the pressure sensing unit, electric characteristics of the pressure sensing unit are changed, and thus the organic thin film transistor can function as a pressure sensor.

When the channel area functions as the pressure sensing unit, the organic thin film transistor may further include an orientation layer to further enhance the crystallinity of the organic semiconductor comprised in the channel area. Examples of the orientation layer may include a monomolecular layer provided so as to be joined to the gate insulating layer by using a silane coupling agent, such as hexamethyldisilazane.

Furthermore, the organic thin film transistor manufactured using the composition of the present invention can be used for the production of a conductivity modulation type sensor. The conductivity modulation type sensor uses a conductivity measuring element as a signal conversion element configured to convert an input signal into an electric signal and output the electric signal. Specifically, a sensitivity function or a selectivity function for an input of a detection target is provided to a film comprising the composition of the present invention. The conductivity modulation type sensor is configured to detect an input of a detection target as a change in the conductivity of the composition of the present invention. Examples of the conductivity modulation type sensor may include a biosensor, a gas sensor, an ion sensor, and a humidity sensor.

Furthermore, the organic thin film transistor manufactured using the composition of the present invention can be used for manufacturing of an amplifying circuit comprising the organic thin film transistor to amplify output signals from various sensors, such as a biosensor, a gas sensor, an ion sensor, a humidity sensor, and a pressure sensor.

Furthermore, the organic thin film transistor manufactured using the composition of the present invention can be used for manufacturing of a sensor array on which a plurality of various sensors, such as a biosensor, a gas sensor, an ion sensor, a humidity sensor, and a pressure sensor, are integrated.

Furthermore, the organic thin film transistor manufactured using the composition of the present invention can be used for manufacturing of a sensor array on which a plurality of various sensors, such as a biosensor, a gas sensor, an ion sensor, a humidity sensor, and a pressure sensor, are integrated and which is equipped with an amplifying circuit comprising the organic thin film transistor to amplify output signals from the sensors.

### EXAMPLES

Hereinafter, the present invention will be described using examples. The present invention is not limited by the following examples. A suffix to a parenthesis in formulae shown in descriptions of the following examples indicates the mole fraction of a repeating unit.

### Synthesis Example 1

In a 50 mL pressure resistant vessel (manufactured by Ace Glass Incorporated), 1.69 g of styrene (manufactured by Wako Pure Chemical Industries, Ltd.), 4.32 g of 2,3,4,5,6-pentafluorobenzyl methacrylate (manufactured by SynQuest Laboratories), 1.30 g of 2-[O-[1′-methylpropylideneamino]carboxyamino]ethyl-methacrylate (trade name “Karenz MOI-BM”, manufactured by SHOWA DENKO K. K.), 2.03 g of 2-cyanoethyl acrylate (manufactured by Tokyo Chemical Industry Co., ltd.), 0.05 g of 2,2′-azobis(2-methylpropionitrile), and 22.03 g of 2-heptanone (manufactured by Tokyo Chemical Industry Co., Ltd.) were fed, and subjected to bubbling with nitrogen gas, and then the vessel was sealed hermetically. It was polymerized in an oil bath at 60° C. for 24 hours to obtain a viscous 2-heptanone solution in which a polymer compound (1) having a repeating unit and a composition shown below was dissolved.

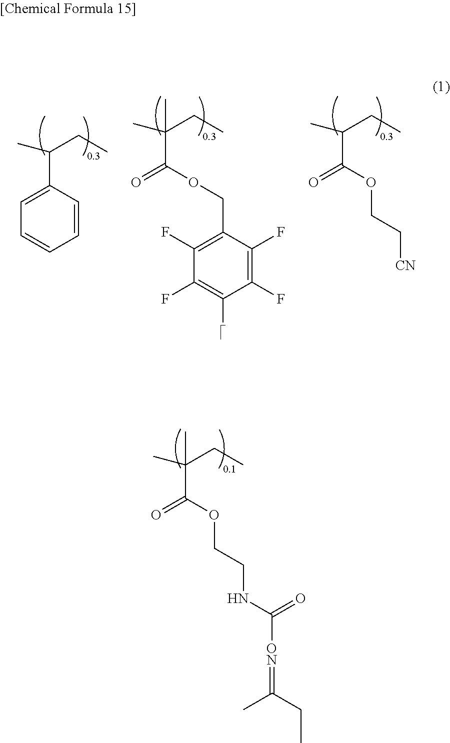

The obtained polymer compound (1) had a standard polystyrene-equivalent weight-average molecular weight of 77,000 (A GPC system manufactured by SHIMADZU CORPORATION, Tskgel super HM-H (one column), and Tskgel super H2000 (one column) were used, and THF was used as a mobile phase).

### Synthesis Example 2

In a 50 mL pressure resistant vessel (manufactured by Ace Glass Incorporated), 1.84 g of styrene (manufactured by Wako Pure Chemical Industries, Ltd.), 4.70 g of 2,3,4,5,6-pentafluorobenzyl methacrylate (manufactured by SynQuest Laboratories), 0.70 g of 4-aminostyrene (manufactured by Tokyo Chemical Industry Co., Ltd.), 2.21 g of 2-cyanoethyl acrylate (manufactured by Tokyo Chemical Industry Co., Ltd.), 0.05 g of 2,2′-azobis(2-methylpropionitrile), and 22.25 g of 2-heptanone (manufactured by Tokyo Chemical Industry Co., Ltd.) were fed, and subjected to bubbling with nitrogen gas, and then the vessel was sealed hermetically. It was polymerized in an oil bath at 60° C. for 24 hours to obtain a viscous 2-heptanone solution in which a polymer compound (2) having a repeating unit and a composition shown below was dissolved.

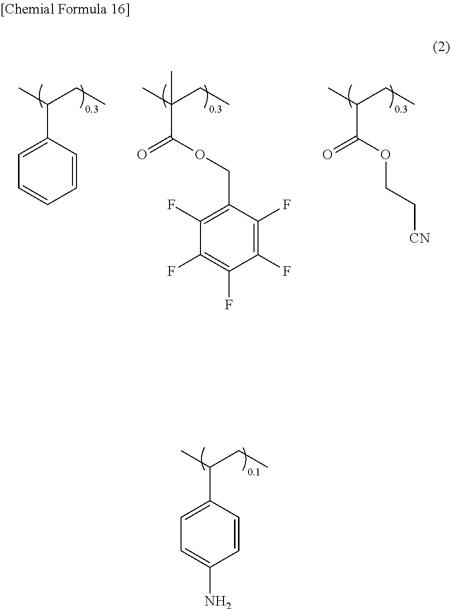

The obtained polymer compound (2) had a standard polystyrene-equivalent weight-average molecular weight of 66,000 (The GPC system manufactured by SHIMADZU CORPORATION, Tskgel super HM-H (one column), and Tskgel super H2000 (one column) were used, and THF was used as a mobile phase).

### Synthesis Example 3

A polymer compound (3) was synthesized in accordance with the following scheme.

Gas in a reaction vessel was replaced with nitrogen gas, and then, a compound B-1 (286.8 mg, 0.200 mmol), a compound A-2 (77.6 mg, 0.200 mmol), 19 mL of tetrahydrofuran, 7.3 mg of tris(dibenzylideneacetone)dipalladium, and 9.3 mg of tri-tert-butylphosphonium tetrafluoroborate were added therein, and stirred. To a obtained reaction solution, 1.0 mL of a 3-mol/L potassium phosphate aqueous solution was added dropwise, and was refluxed for 3 hours. To a obtained reaction solution, 24.4 mg of phenylboronic acid was added, and was refluxed for 1 hour. To a obtained reaction solution, 0.1 g of sodium N,N-diethyldithiocarbamate trihydrate was added, and was refluxed for 3 hours. Water was poured into a obtained reaction solution, and toluene was added thereto, then a toluene layer was extracted. After a obtained toluene solution was washed with an acetic acid solution and water, and was purified using a silica gel column. When a obtained toluene solution was added dropwise to acetone; a precipitate was obtained. Using acetone as a solvent, the obtained precipitate was washed by Soxhlet extraction to obtain a polymer compound (3) comprising a repeating unit represented by the following formula. The obtained amount was 244 mg.

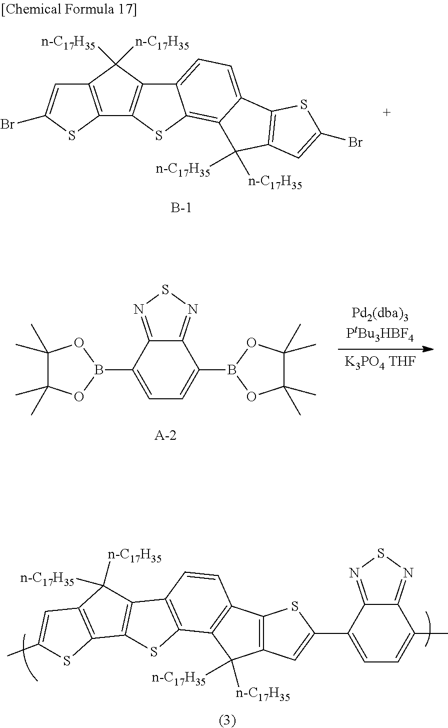

The obtained polymer compound (3) had a standard polystyrene-equivalent weight-average molecular weight of 650,000 (The GPC system manufactured by SHIMADZU CORPORATION, Tskgel super HM-H (one column), and Tskgel super H2000 (one column) were used, and THF was used as a mobile phase).

### Synthesis Example 4

In a 50 mL pressure resistant vessel (manufactured by Ace Glass Incorporated), 2.60 g of styrene (manufactured by Wako Pure Chemical Industries, Ltd.), 4.85 g of 2,3,4,5,6-pentafluorostyrene (manufactured by Aldrich), 2.00 g of 2-[O-[1′-methylpropylideneamino]carboxyamino]ethyl-methacrylate (trade name “Karenz MOI-BM”, manufactured by SHOWA DENKO K. K.), 3.13 g of 2-cyanoethyl acrylate (manufactured by Tokyo Chemical Industry Co., Ltd.), 0.06 g of 2,2′-azobis(2-methylpropionitrile), and 8.43 g of 2-heptanone (manufactured by Tokyo Chemical Industry Co., Ltd.) were fed, and subjected to bubbling with nitrogen gas, and then the vessel was sealed hermetically. It was polymerized in an oil bath at 60° C. for 24 hours to obtain a viscous 2-heptanone solution in which a polymer compound (4) having a repeating unit and a composition shown below was dissolved.

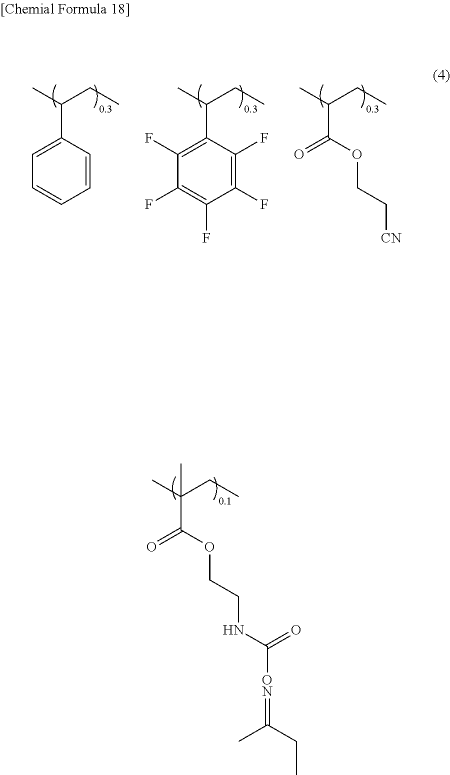

The obtained polymer compound (4) had a standard polystyrene-equivalent weight-average molecular weight of 289,000 (The GPC system manufactured by SHIMADZU CORPORATION, Tskgel super HM-H (one column), and Tskgel super H2000 (one column) were used, and THF was used as a mobile phase).

### Synthesis Example 5

In a 50 mL pressure resistant vessel (manufactured by Ace Glass Incorporated), 1.31 g of styrene (manufactured by Wako Pure Chemical Industries, Ltd.), 2.45 g of 2,3,4,5,6-pentafluorostyrene (manufactured by Aldrich), 0.50 g of 4-aminostyrene (manufactured by Tokyo Chemical Industry Co., Ltd.), 1.58 g of 2-cyanoethyl acrylate (manufactured by Tokyo Chemical Industry Co., Ltd.), 0.06 g of 2,2′-azobis(2-methylpropionitrile), and 13.75 g of 2-heptanone (manufactured by Tokyo Chemical Industry Co., Ltd.) were fed, and subjected to bubbling with nitrogen gas, and then the vessel was sealed hermetically. It was polymerized in an oil bath at 60° C. for 24 hours to obtain a viscous 2-heptanone solution in which a polymer compound (5) having a repeating unit and a composition shown below was dissolved.

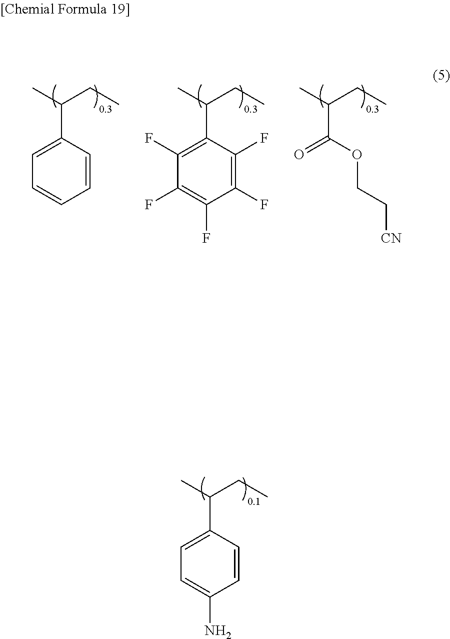

The obtained polymer compound (5) had a standard polystyrene-equivalent weight-average molecular weight of 149,000 (The GPC system manufactured by SHIMADZU CORPORATION, Tskgel super HM-H (one column), and Tskgel super H2000 (one column) were used, and THF was used as a mobile phase).

### Synthesis Example 6

In a 50 mL pressure resistant vessel (manufactured by Ace Glass Incorporated), 2.06 g of styrene (manufactured by Wako Pure Chemical Industries, Ltd.), 2.43 g of 2,3,4,5,6-pentafluorostyrene (manufactured by Aldrich), 1.00 g of 2-[O-[1′-methylpropylideneamino]carboxyamino]ethyl-methacrylate (trade name “Karenz MOI-BM”, manufactured by SHOWA DENKO K. K.), 0.06 g of 2,2′-azobis(2-methylpropionitrile), and 14.06 g of 2-heptanone (manufactured by Tokyo Chemical Industry Co., Ltd.) were fed, and subjected to bubbling with nitrogen gas, and then the vessel was sealed hermetically. It was polymerized in an oil bath at 60° C. for 16 hours to obtain a viscous 2-heptanone solution in which a polymer compound (6) having a repeating unit and a composition shown below was dissolved.

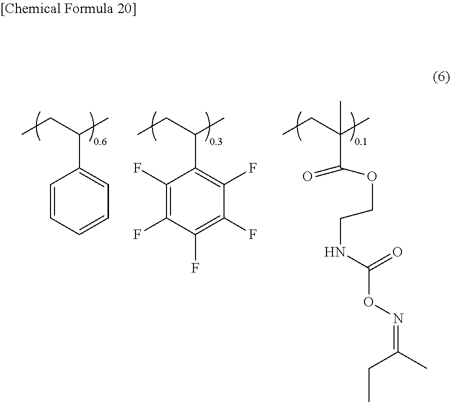

The obtained polymer compound (6) had a standard polystyrene-equivalent weight-average molecular weight of 169,000 (The GPC system manufactured by SHIMADZU. CORPORATION, Tskgel super HM-H (one column), and Tskgel super H2000 (one column) were used, and THF was used as a mobile phase).

### Synthesis Example 7

In a 125 mL pressure resistant vessel (manufactured by Ace Glass Incorporated), 3.50 g of 4-aminostyrene (manufactured by Aldrich), 13.32 g of 2,3,4,5,6-pentafluorostyrene (manufactured by Aldrich), 0.08 g of 2,2′-azobis(2-methylpropionitrile), and 25.36 g of 2-heptanone (manufactured by Tokyo Chemical Industry Co., Ltd.) were fed, and subjected to bubbling with nitrogen gas, and then the vessel was sealed hermetically. It was polymerized in an oil bath at 60° C. for 48 hours to obtain a viscous 2-heptanone solution in which a polymer compound (7) having a repeating unit and a composition shown below was dissolved.

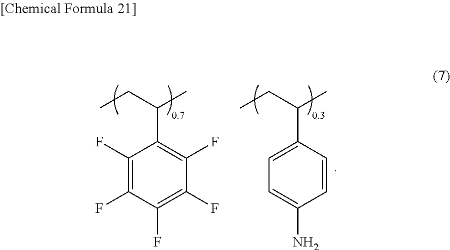

The obtained polymer compound (7) had a standard polystyrene-equivalent weight-average molecular weight of 243,000 (The GPC system manufactured by SHIMADZU CORPORATION, Tskgel super HM-H (one column), and Tskgel super H2000 (one column) were used, and THF was used as a mobile phase).

### Synthesis Example 8

In a 50 mL pressure resistant vessel (manufactured by Ace Glass Incorporated), 4.99 g of 2,3,4,5,6-pentafluorobenzyl methacrylate (manufactured by SynQuest Laboratories), 0.50 g of 2-[O-[1′-methylpropylideneamino]carboxyamino]ethyl-methacrylate (trade name “Karenz MOI-BM”, manufactured by SHOWA DENKO K. K.), 0.05 g of 2,2′-azobis(2-methylpropionitrile), and 12.94 g of 2-heptanone (manufactured by Tokyo Chemical Industry Co., Ltd.) were fed, and subjected to bubbling with nitrogen gas, and then the vessel was sealed hermetically. It was polymerized in an oil bath at 60° C. for 24 hours to obtain a viscous 2-heptanone solution in which a polymer compound (8) having a repeating unit and a composition shown below was dissolved.

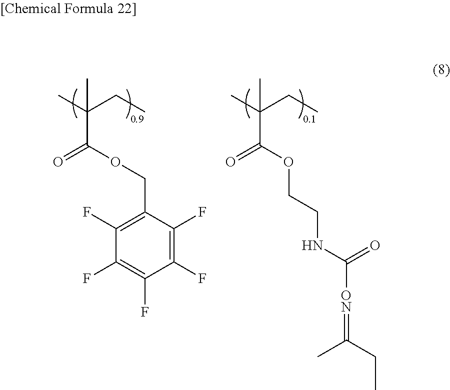

The obtained polymer compound (8) had a standard polystyrene-equivalent weight-average molecular weight of 56,000 (The GPC system manufactured by SHIMADZU CORPORATION, Tskgel super HM-H (one column), and Tskgel super H2000 (one column) were used, and THF was used as a mobile phase).

### Synthesis Example 9

In a 50 mL pressure resistant vessel (manufactured by Ace Glass Incorporated), 7.28 g of 2,3,4,5,6-pentafluorostyrene (manufactured by Aldrich), 1.00 g of 2-[O-[1′-methylpropylideneamino]carboxyamino]ethyl-methacrylate (trade name “Karenz MOI-BM”, manufactured by SHOWA DENKO K. K.), 0.08 g of 2,2′-azobis(2-methylpropionitrile), and 19.51 g of 2-heptanone (manufactured by Tokyo Chemical Industry Co., Ltd.) were fed, and subjected to bubbling with nitrogen gas, and then the vessel was sealed hermetically. It was polymerized in an oil bath at 80° C. for 10 hours to obtain a viscous 2-heptanone solution in which a polymer compound (9) having a repeating unit and a composition shown below was dissolved.

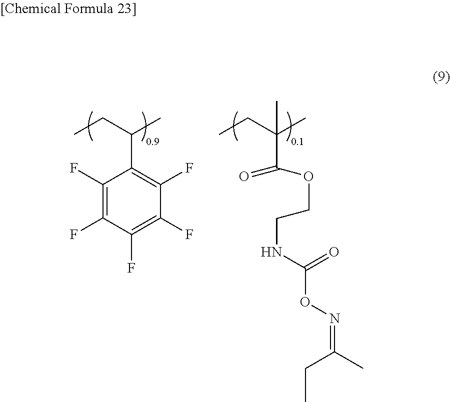

The obtained polymer compound (9) had a standard polystyrene-equivalent weight-average molecular weight of 27,000 (The GPC system manufactured by SHIMADZU CORPORATION, Tskgel super HM-H (one column), and Tskgel super H2000 (one column) were used, and THF was used as a mobile phase).

### Synthesis Example 10

In a 50 mL pressure resistant vessel (manufactured by Ace Glass Incorporated), 4.93 g of 2,3,4,5,6-pentafluorobenzyl methacrylate (manufactured by SynQuest Laboratories), 0.50 g of 2-[O-[1′-methylpropylideneamino]carboxyamino]ethyl-methacrylate (trade name “Karenz MOI-BM”, manufactured by SHOWA DENKO K. K.), 0.11 g of 3,3,4,4,5,5,6,6,7,7,8,8,9,9,10,10,10-heptadecafluorodecyl methacrylate (manufactured by Wako-Pure Chemical Industries, Ltd.), 0.03 g of 2,2′-azobis(2-methylpropionitrile), and 13.07 g of 2-heptanone (manufactured by Tokyo Chemical Industry Co., Ltd.) were fed, and subjected to bubbling with nitrogen gas, and then the vessel was sealed hermetically. The mixture was polymerized in an oil bath at 80° C. for 10 hours to obtain a viscous 2-heptanone solution in which a polymer compound (10) having a repeating unit and a composition shown below was dissolved.

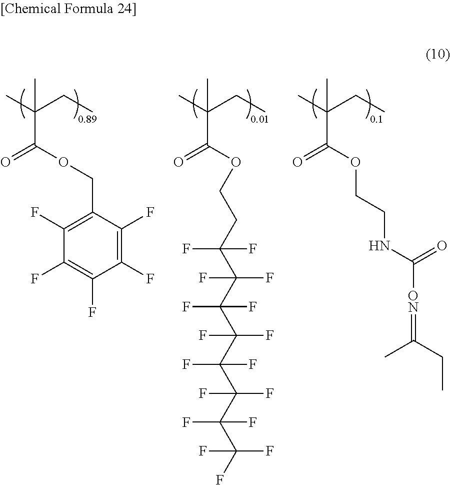

The obtained polymer compound (10) had a standard polystyrene-equivalent weight-average molecular weight of 25,000 (The GPC system manufactured by SHIMADZU CORPORATION, Tskgel super HM-H (one column), and Tskgel super H2000 (one column) were used, and THF was used as a mobile phase).

### Synthesis Example 11

The inside of a 300 mL three neck flask to which a 100 mL equilibrium shape dropping funnel and a Dimroth provided with a three-way cock were attached was replaced with nitrogen gas. In the three neck flask, 100 g of 2-(2-isocyanatoethyloxy]ethyl-methacrylate (trade name “Karenz MOI-EG”, manufactured by SHOWA DENKO K. K.), 50 mL of dehydrated tetrahydrofuran (manufactured by Wako Pure Chemical Industries, Ltd.), and a stirrer bar were placed. While it was stirred with a magnetic stirrer, 41.59 g of 2-butanone oxime (manufactured by Wako Pure Chemical Industries, Ltd.) was slowly added dropwise thereto from the equilibrium shape dropping funnel at normal temperature so that it was allowed to reaction. After the dropwise addition was completed, it was further stirred at normal temperature for 24 hours so as to be allowed to reaction. After the reaction was completed, 10 mL of ion exchange water was added so that unreacted isocyanate was quenched to obtain a reaction mixture. To the reaction mixture, 100 mL of acetone was added, and furthermore anhydrous magnesium sulfate was added, and it was left standing overnight to dry the reaction mixture. An insoluble matter was filtered off from the dry reaction mixture, and a filtrate was concentrated by a rotary evaporator to obtain 2-{2-[O-[1′-methylpropylideneamino]carboxyamino]ethyloxy}ethyl-methacrylate serving as a target substance, which is represented by the following formula, in the form of a viscous liquid. The obtained amount was 139 g.

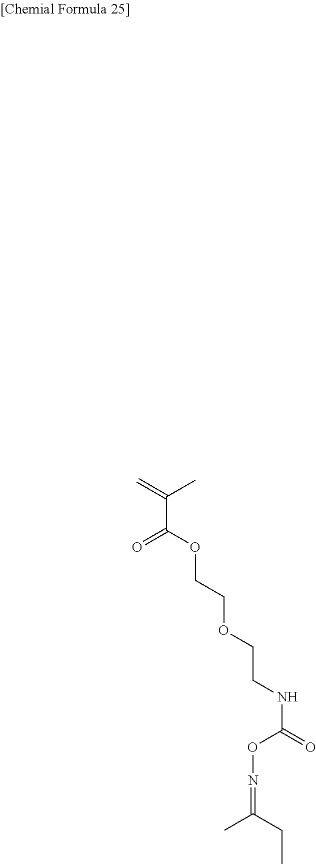 [SMILES: C=C(C)C(=O)OCCOCCNC(=O)ON=C(C)CC]

In a 50 mL pressure resistant vessel (manufactured by Ace Glass Incorporated), 4.19 g of 2,3,4,5,6-pentafluorobenzyl methacrylate (manufactured by SynQucst Laboratories), 0.50 g of the synthesized 2-{2-[O-[1′-methylpropylideneamino]carboxyamino]ethyloxy)}ethyl-methacrylate, 0.05 g of 2,2′-azobis(2-methylpropionitrile), and 11.04 g of 2-heptanone (manufactured by Tokyo Chemical Industry Co., Ltd.) were fed, and subjected to bubbling with nitrogen gas, and then the vessel was sealed hermetically. It was polymerized in an oil bath at 80° C. for 10 hours to obtain a viscous 2-heptanone solution in which a polymer compound (11) having a repeating unit and a composition shown below was dissolved.

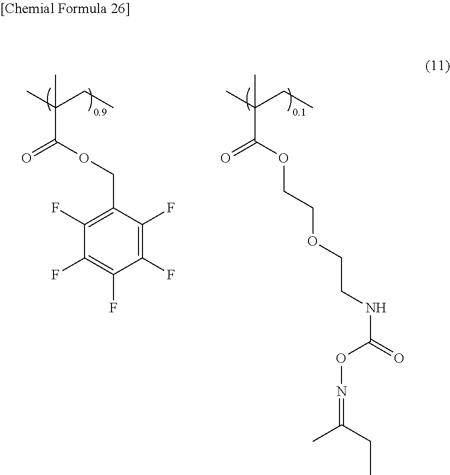

The obtained polymer compound (11) had a standard polystyrene-equivalent weight-average molecular weight of 62,000 (The GPC system manufactured by SHIMADZU CORPORATION, Tskgel super HM-H (one column), and Tskgel super H2000 (one column) were used, and THF was used as a mobile phase).

### Synthesis Example 12

In a 50 mL pressure resistant vessel (manufactured by Ace Glass Incorporated), 8.28 g of 2,3,4,5,6-pentafluorobenzyl methacrylate (manufactured by SynQuest Laboratories), 1.00 g of the 2-{2-[O-[1′-methylpropylideneamino]carboxyamino]ethyloxy)}ethyl-methacrylate synthesized in Synthesis Example 11, 0.19 g of 3,3,4,4,5,5,6,6,7,7,8,8,9,9,10,10,10-heptadecafluorodecyl methacrylate (manufactured by Wako Pure Chemical Industries, Ltd.), 0.09 g of 2,2′-azobis(2-methylpropionitrile), and 22.30 g of 2-heptanone (manufactured by Tokyo Chemical Industry Co., Ltd.) were fed, and subjected to bubbling with nitrogen gas, and then the vessel was sealed hermetically. It was polymerized in an oil bath at 80° C. for 10 hours to obtain a viscous 2-heptanone solution in which a polymer compound (12) having a repeating unit and a composition shown below was dissolved.

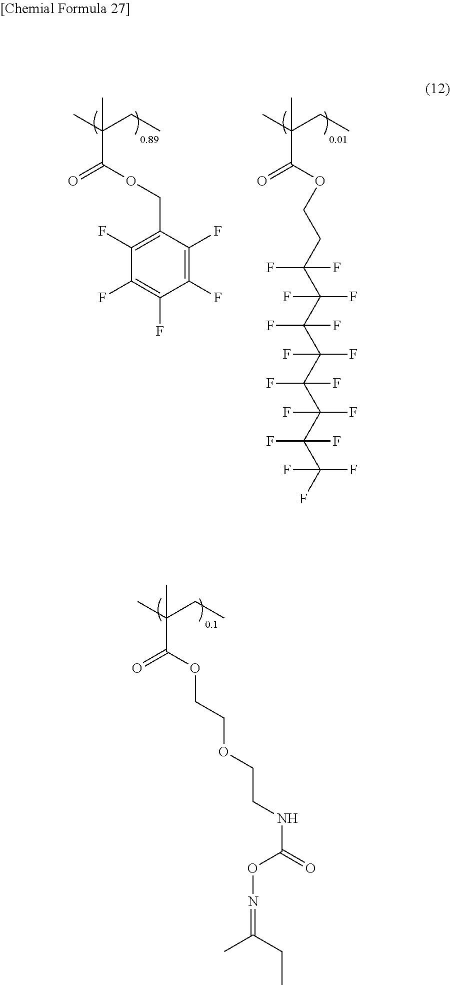

The obtained polymer compound (12) had a standard polystyrene-equivalent weight-average molecular weight of 64,000 (The GPC system manufactured by SHIMADZU CORPORATION, Tskgel super HM-H (one column), and Tskgel super H2000 (one column) were used, and THF was used as a mobile phase).

### Synthesis Example 13

In a 50 mL pressure resistant vessel (manufactured by Ace Glass Incorporated), 2.79 g of 2,3,4,5,6-pentafluorobenzyl methacrylate (manufactured by SynQuest Laboratories), 1.00 g of the 2-{2-[O-[1′-methylpropylideneamino]carboxyamino]ethyloxy)}ethyl-methacrylate synthesized in Synthesis Example 11, 0.37 g of 3,3,4,4,5,5,6,6,7,7,8,8,9,9,10,10,10-heptadecafluorodecyl methacrylate (manufactured by Wako Pure Chemical Industries, Ltd.), 2.11 g of styrene (manufactured by JUNSEI CHEMICAL CO., LTD.), 0.06 g of 2,2′-azobis(2-methylpropionitrile), and 14.78 g of 2-heptanone (manufactured by Tokyo Chemical Industry Co., Ltd.) were fed, and subjected to bubbling with nitrogen gas, and then the vessel was sealed hermetically. It was polymerized in an oil bath at 80° C. for 10 hours to obtain a viscous 2-heptanone solution in which a polymer compound (13) having a repeating unit and a composition shown below was dissolved.

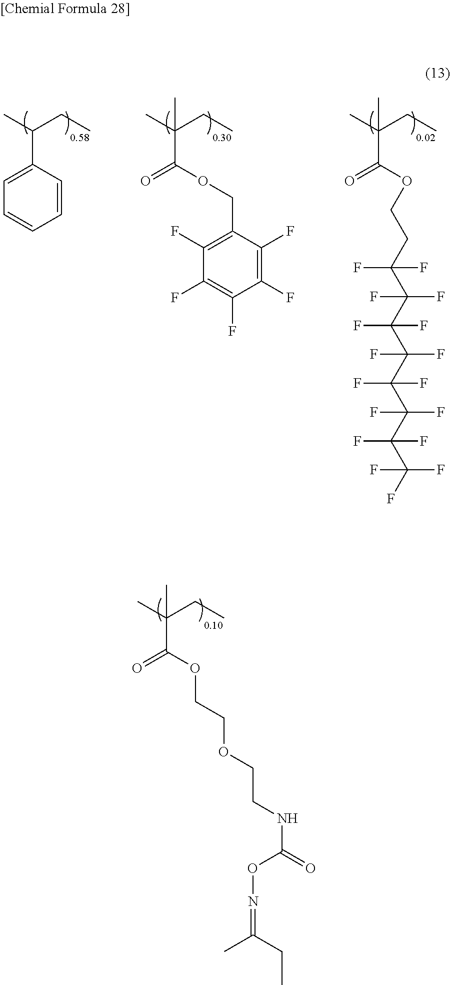

The obtained polymer compound (13) had a standard polystyrene-equivalent weight-average molecular weight of 40,000 (The GPC system manufactured by SHIMADZU CORPORATION, Tskgel super HM-H (one column), and Tskgel super H2000 (one column) were used, and THF was used as a mobile phase).

### Synthesis Example 14

In a 50 mL pressure resistant vessel (manufactured by Ace Glass Incorporated), 1.55 g of 2,3,4,5,6-pentafluorobenzyl methacrylate (manufactured by SynQuest Laboratories), 0.70 g of 2-[O-[1′-methylpropylideneamino]carboxyamino]ethyl-methacrylate (trade name “Karenz MOI-BM”, manufactured by SHOWA DENKO K. K.), 0.91 g of styrene (manufactured by JUNSEI CHEMICAL CO., LTD.), 1.46 g of 2-cyanoethyl acrylate (manufactured by Tokyo Chemical Industry Co., Ltd.), 0.03 g of 2,2′-azobis(2-methylpropionitrile), and 10.89 g of 2-heptanone (manufactured by Tokyo Chemical Industry Co., Ltd.) were fed, and subjected to bubbling with nitrogen gas, and then the vessel was sealed hermetically. It was polymerized in an oil bath at 80° C. for 10 hours to obtain a viscous 2-heptanone solution in which a polymer compound (14) having a repeating unit and a composition shown below was dissolved.

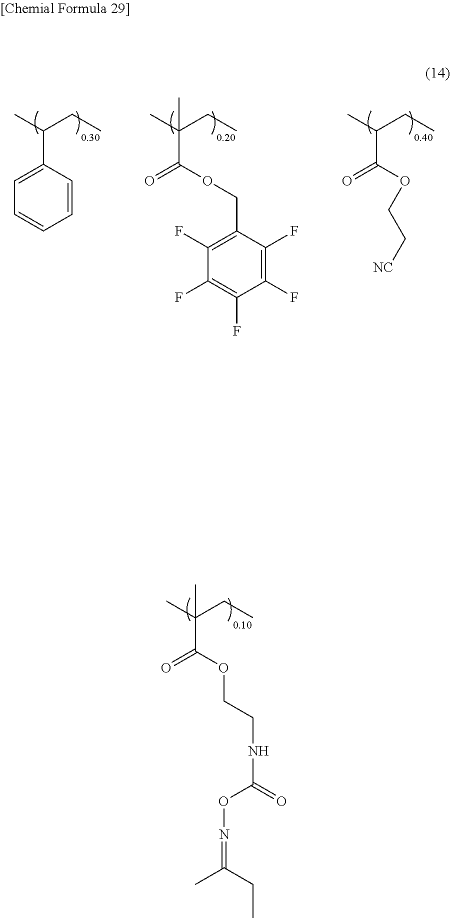

The obtained polymer compound (14) had a standard polystyrene-equivalent weight-average molecular weight of 74,000 (The GPC system manufactured by SHIMADZU CORPORATION, Tskgel super HM-H (one column), and Tskgel super H2000 (one column) were used, and THF was used as a mobile phase).

### Synthesis Example 15

In a 50 mL pressure resistant vessel (manufactured by Ace Glass Incorporated), 1.79 g of 2,3,4,5,6-pentafluorobenzyl methacrylate (manufactured by SynQuest Laboratories), 0.40 g of 4-aminostyrene (manufactured by Aldrich), 1.05 g of styrene (manufactured by JUNSEI CHEMICAL CO., LTD.), 1.68 g of 2-cyanoethyl acrylate (manufactured by Tokyo Chemical Industry Co., Ltd.), 0.03 g of 2,2′-azobis(2-methylpropionitrile), and 11.60 g of 2-heptanone (manufactured by Tokyo Chemical Industry Co., Ltd.) were fed, and subjected to bubbling with nitrogen gas, and then the vessel was sealed hermetically. It was polymerized in an oil bath at 80° C. for 10 hours to obtain a viscous 2-heptanone solution in which a polymer compound (15) having a repeating unit and a composition shown below was dissolved.

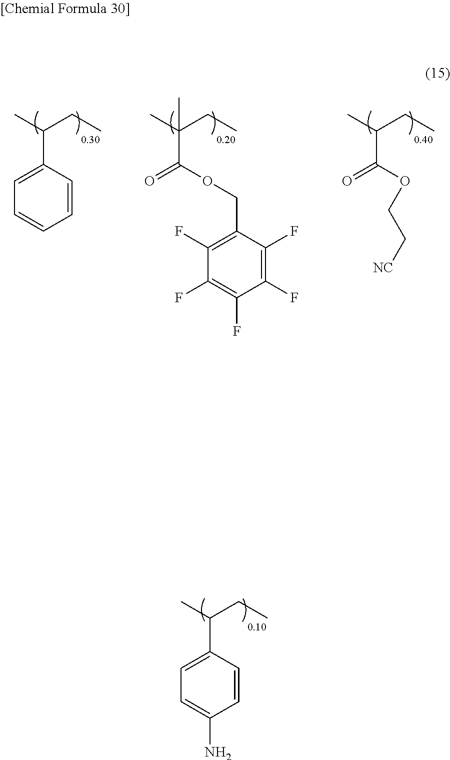

The obtained polymer compound (15) had a standard polystyrene-equivalent weight-average molecular weight of 86,000 (The GPC system manufactured by SHIMADZU CORPORATION, Tskgel super HM-H (one column), and Tskgel super H2000 (one column) were used, and THF was used as a mobile phase).

### Synthesis Example 16

In a 50 mL pressure resistant vessel (manufactured by Ace Glass Incorporated), 3.72 g of 2,3,4,5,6-pentafluorobenzyl methacrylate (manufactured by SynQuest Laboratories), 2.00 g of the 2-{2-[O-[1′-methylpropylideneamin]olcarboxyamino]ethyloxy)}ethyl-methacrylate synthesized in Synthesis Example 11, 4.03 g of 4-[(1-ethoxy)ethoxy]styrene (manufactured by TOSOH ORGANIC CHEMICAL Co, Ltd.), 3.50 g of 2-cyanoethyl acrylate (manufactured by Tokyo Chemical Industry Co., Ltd.), 0.07 g of 2,2′-azobis(2-methylpropionitrile), and 20.07 g of 2-heptanone (manufactured by Tokyo Chemical Industry Co., Ltd.) were fed, and subjected to bubbling with nitrogen gas, and then the vessel was sealed hermetically. It was polymerized in an oil bath at 80° C. for 10 hours to obtain a viscous 2-heptanone solution in which a polymer compound (16) having a repeating unit and a composition shown below was dissolved.

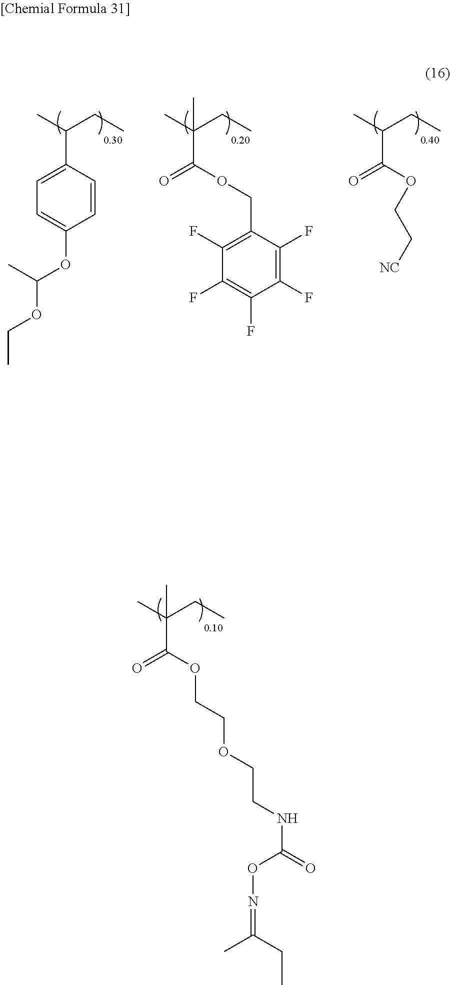

The obtained polymer compound (16) had a standard polystyrene-equivalent weight-average molecular weight of 283,000 (The GPC system manufactured by SHIMADZU CORPORATION, Tskgel super HM-H (one column), and Tskgel super H2000 (one column) were used, and THF was used as a mobile phase).

### Synthesis Example 17

Into a 200 mL three neck flask to which a Dimroth having a three-way cock attached to the upper part thereof was attached, 25.45 g of 4-vinyl benzoic acid (manufactured by Aldrich), 50 g of 3,4-dihydro-2H-pyran, the catalytic amount of concentrated hydrochloric acid, and a stirring bar were placed, and air inside the three neck flask was replaced with nitrogen. The three neck flask was soaked in an oil bath at 50° C., and it was allowed to reaction for 2 hours while being stirred by a magnetic stirrer and the stirring bar. After the reaction was completed, a reaction mixture was transferred to a 300 mL separating funnel, and 100 mL of diethylether was added thereto. After that, a sodium hydroxide solution was added to rinse an organic layer until a water layer became alkaline, and the organic layer was separated. The rinsing of the resultant organic layer was repeated 3 times by using 50 mL of ion-exchange water. After that, the organic layer was separated, and the anhydrous magnesium sulfate was added thereto to dry the organic layer. After anhydrous magnesium sulfate was filtered off from the organic layer, a filtrate was concentrated using a rotary evaporator to obtain a 4-vinylbcnzoic acid tetrahydropyranyl ester represented by the following formula in the form of a clear and colorless liquid. The obtained amount was 38.25 g, and the yield was 96%.

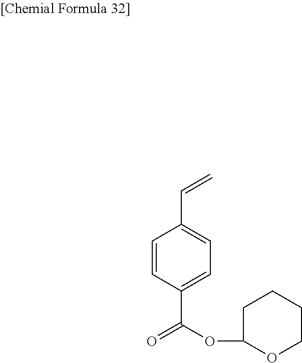 [SMILES: C=Cc1ccc(C(=O)OC2CCCCO2)cc1]

In a 50 mL pressure resistant vessel (manufactured by Ace Glass Incorporated), 0.65 g of 2,3,4,5,6-pentafluorobenzyl methacrylate (manufactured by SynQuest Laboratories), 1.70 g of the synthesized 4-vinylbenzoic acid tetrahydropyranyl ester, 0.94 g of 4-[(1-ethoxy)ethoxy]styrene (manufactured by TOSOH ORGANIC CHEMICAL Co, Ltd.), 1.22 g of 2-cyanoethyl acrylate (manufactured by Tokyo Chemical Industry Co., Ltd.), 0.03 g of 2,2′-azobis(2-methylpropionitrile), and 6.83 g of 2-heptanone (manufactured by Tokyo Chemical Industry Co., Ltd.) were fed, and subjected to bubbling with nitrogen gas, and then the vessel was sealed hermetically. It was polymerized in an oil bath at 80° C. for 10 hours to obtain a viscous 2-heptanone solution in which a polymer compound (17) having a repeating unit and a composition shown below was dissolved.

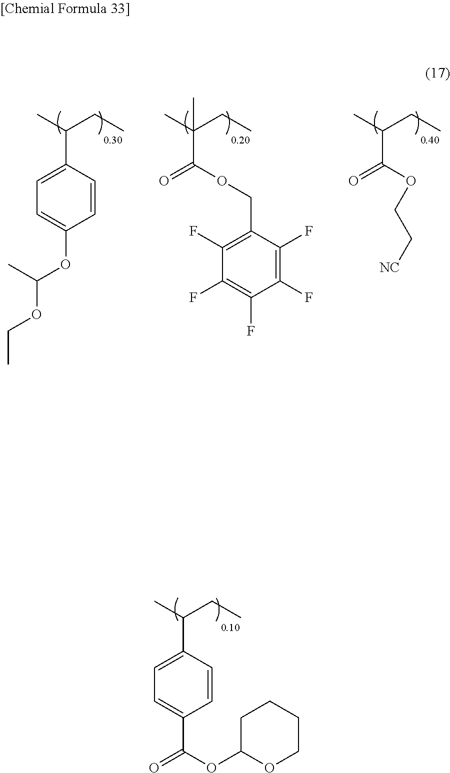

The obtained polymer compound (17) had a standard polystyrene-equivalent weight-average molecular weight of 121,000 (The GPC system manufactured by SHIMADZU CORPORATION, Tskgel super HM-H (one column), and Tskgel super H2000 (one column) were used, and THF was used as a mobile phase).

### Synthesis Example 18

In a 50 mL pressure resistant vessel (manufactured by Ace Glass Incorporated), 7.10 g of 2,3,4,5,6-pentafluorobenzyl methacrylate (manufactured by SynQuest Laboratories), 0.80 g of 2-[O-[1′-methylpropylideneamino]carboxyamino]ethyl-methacrylate (trade name “Karenz MOI-BM”, manufactured by SHOWA DENKO K. K.), 0.48 g of 4-hydroxybutyl acrylate (manufactured by Nihon Kasei CO., LTD.), 0.04 g of 2,2′-azobis(2-methylpropionitrile), and 19.74 g of 2-heptanone (manufactured by Tokyo Chemical Industry Co., Ltd.) were fed, and subjected to bubbling with nitrogen gas, and then the vessel was sealed hermetically. It was polymerized in an oil bath at 80° C. for 10 hours to obtain a viscous 2-heptanone solution in which a polymer compound (18) having a repeating unit and a composition shown below was dissolved.

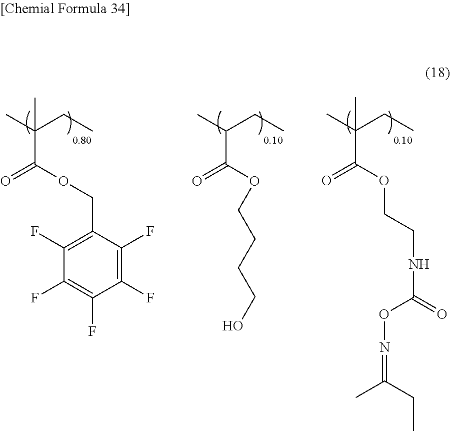

The obtained polymer compound (18) had a standard polystyrene-equivalent weight-average molecular weight of 73,000 (The GPC system manufactured by SHIMADZU CORPORATION, Tskgel super HM-H (one column), and Tskgel super H2000 (one column) were used, and THF was used as a mobile phase).

### Example 1

In a 125 mL sample bottle, 30.72 g of the 2-heptanone solution of the polymer compound (1) obtained in the above described Synthesis Example 1, 28.57 g of the 2-heptanone solution of the polymer compound (2) obtained in Synthesis Example 2, and 29.65 g of 2-heptanone were placed, and dissolved with stirring to prepare a uniform coating solution (1).

The obtained coating solution (1) was filtered using a membrane filter having a pore diameter of 0.2 μm. A glass substrate provided with a chromium layer was prepared, and the chromium layer was patterned by a photolithography process and an etching process to form a gate electrode. Onto the gate electrode side of the glass substrate having the gate electrode formed therein, the coating solution (1) was applied by spin coating method, and then baked on a hot plate at 180° C. for 30 minutes to form a gate insulating layer. The formed gate insulating layer had a thickness of 650 nm.

Next, on the gate insulating layer side of the glass substrate having the gate insulating layer formed therein, a gold layer was pattern-formed by vacuum deposition to form a source electrode and a drain electrode. Here, a channel length was 20 μm and a channel width was 2 mm.

Subsequently, the glass substrate having gate electrode, the gate insulating layer, the source electrode, and the drain electrode formed therein was immersed in an isopropyl alcohol dilute solution of pentafluorobenzenethiol for 2 minutes to modify surfaces of the source electrode and the drain electrode formed on the gate insulating layer.

Next, the polymer compound (3) was dissolved in toluene serving as a solvent to prepare a solution (organic semiconductor composition) having a concentration of 0.5% by mass, and the resultant solution was filtered with the membrane filter to be a coating solution (2).

The obtained coating solution (2) was applied, by spin coating method, onto the gate insulating layer provided with the source electrode and drain electrode each having the modified surface, and dried by heat-treatment on a hot plate at 120° C. for 30 minutes to form an active layer having a thickness of about 60 nm, whereby a bottom-gate bottom-contact type organic thin film transistor (1) was manufactured.

The obtained organic transistor (1) was evaluated. Specifically, under conditions such that a voltage was applied to the gate electrode of the organic thin film transistor (1) and a gate voltage Vg was changed from 20 V to −40 V and a voltage Vsd between the source and drain electrodes was changed from 0 V to −40 V, characteristics of the transistor were measured and evaluated using a vacuum prober (BCT22MDC-5-HT-SCU, manufactured by Nagase Electronic Equipment Service Co., LTD). The results are shown in Table 1 below. The carrier mobility of the organic thin film transistor (1) was 0.46 cm²/Vs.

### Example 2

In a 10 mL sample bottle, 4.00 g of the 2-heptanone solution of the polymer compound (8) obtained in the above described Synthesis Example 8 and 2.00 g of the 2-heptanone solution of the polymer compound (7) obtained in the above described Synthesis Example 7 were placed, and dissolved with stirring to prepare a uniform coating solution (3).

A bottom-gate bottom-contact type organic thin film transistor (2) was manufactured in the same manner as in the above described Example 1, except that the coating solution (3) was used for the formation of a gate insulating layer, and characteristics of the transistor were measured and evaluated. The formed gate insulating layer had a thickness of 630 nm. The results are shown in Table 1 below.

### Example 3

In a 20 mL sample bottle, 5.00 g of the 2-heptanone solution of the polymer compound (1) obtained in the above described Synthesis Example 1, 0.50 g of the 2-heptanone solution of the polymer compound (8) obtained in the above described Synthesis Example 8, and 2.75 g of 2-heptanone were placed, and dissolved with stirring to prepare a uniform coating solution (4).

A bottom-gate bottom-contact type organic thin film transistor (3) was manufactured in the same manner as in Example 1, except that the coating solution (4) was used for the formation of a gate insulating layer, and characteristics of the transistor were measured and evaluated. The formed gate insulating layer had a thickness of 690 nm. The results are shown in Table 1 below.

### Example 4

In a 20 mL sample bottle, 5.00 g of the 2-heptanone solution of the polymer compound (1) obtained in the above described Synthesis Example 1, 0.50 g of the 2-heptanone solution of the polymer compound (9) obtained in the above described Synthesis Example 9, and 2.75 g of 2-heptanone were placed, and dissolved with stirring to prepare a uniform coating solution (5).

A bottom-gate bottom-contact type organic thin film transistor (4) was manufactured in the same manner as in Example 1, except that the coating solution (5) was used for the formation of a gate insulating layer, and characteristics of the transistor were measured and evaluated. The formed gate insulating layer had a thickness of 650 nm. The results are shown in Table 1 below.

### Example 5

In a 150 mL sample bottle, 30.72 g of the 2-heptanone solution of the polymer compound (1) obtained in the above described Synthesis Example 1, 28.57 g of the 2-heptanone solution of the polymer compound (2) obtained in the above described Synthesis Example 2, 5.93 g of the 2-heptanone solution of the polymer compound (9) obtained in the above described Synthesis Example 9, and 32.61 g of 2-heptanone were placed, and dissolved with stirring to prepare a uniform coating solution (6).

A bottom-gate bottom-contact type organic thin film transistor (5) was manufactured in the same manner as in the above described Example 1, except that the coating solution (6) was used for the formation of a gate insulating layer, and characteristics of the transistor were measured and evaluated. The formed gate insulating layer had a thickness of 610 nm. The results are shown in Table 1 below.

### Example 6

In a 10 mL sample bottle, 4.00 g of the 2-heptanone solution of the polymer compound (10) obtained in the above described Synthesis Example 10 and 2.00 g of 2-heptanone were placed, and dissolved with stirring to prepare a uniform coating solution (7).

A bottom-gate bottom-contact type organic thin film transistor (6) was manufactured in the same manner as in the above described Example 1, except that the coating solution (7) was used for the formation of a gate insulating layer, and characteristics of the transistor were measured and evaluated. The formed gate insulating layer had a thickness of 600 nm. The results are shown in Table 1 below.

### Example 7

In a 10 mL sample bottle, 4.00 g of the 2-heptanone solution of the polymer compound (11) obtained in the above described Synthesis Example 11 and 2.00 g of 2-heptanone were placed, and dissolved with stirring to prepare a uniform coating solution (8).

A bottom-gate bottom-contact type organic thin film transistor (7) was manufactured in the same manner as in the above described Example 1, except that the coating solution (8) was used for the formation of a gate insulating layer, and characteristics of the transistor were measured and evaluated. The formed gate insulating layer had a thickness of 600 nm. The results are shown in Table 1 below.

### Example 8

In a 10 mL sample bottle, 4.00 g of the 2-heptanone solution of the polymer compound (12) obtained in the above described Synthesis Example 12 and 2.00 g of 2-heptanone were placed, and dissolved with stirring to prepare a uniform coating solution (9).

A bottom-gate bottom-contact type organic thin film transistor (8) was manufactured in the same manner as in the above described Example 1, except that the coating solution (9) was used for the formation of a gate insulating layer, and characteristics of the transistor were measured and evaluated. The formed gate insulating layer had a thickness of 600 nm. The results are shown in Table 1 below.

### Example 9

In a 10 mL sample bottle, 4.00 g of the 2-heptanone solution of the polymer compound (13) obtained in the above described Synthesis Example 13 and 2.00 g of 2-heptanone were placed, and dissolved with stirring to prepare a uniform coating solution (10).

A bottom-gate bottom-contact type organic thin film transistor (9) was manufactured in the same manner as in the above described Example 1, except that the coating solution (10) was used for the formation of a gate insulating layer, and characteristics of the transistor were measured and evaluated. The formed gate insulating layer had a thickness of 600 nm. The results are shown in Table 1 below.

### Example 10

In a 150 mL sample bottle, 30.72 g of the 2-heptanone solution of the polymer compound (1) obtained in the above described Synthesis Example 1, 28.57 g of the 2-heptanone solution of the polymer compound (2) obtained in the above described Synthesis Example 2, 5.93 g of the 2-heptanone solution of the polymer compound (10) obtained in the above described Synthesis Example 10, and 32.61 g of 2-heptanone were placed, and dissolved with stirring to prepare a uniform coating solution (11).

A bottom-gate bottom-contact type organic thin film transistor (10) was manufactured in the same manner as in the above described Example 1, except that the coating solution (11) was used for the formation of a gate insulating layer, and characteristics of the transistor were measured and evaluated. The formed gate insulating layer had a thickness of 600 nm. The results are shown in Table 1 below.

### Example 11

In a 150 mL sample bottle, 30.72 g of the 2-heptanone solution of the polymer compound (1) obtained in the above described Synthesis Example 1, 28.57 g of the 2-heptanone solution of the polymer compound (2) obtained in the above described Synthesis Example 2, 5.93 g of the 2-heptanone solution of the polymer compound (11) obtained in the above described Synthesis Example 11, and 32.61 g of 2-heptanone were placed, and dissolved with stirring to prepare a uniform coating solution (12).

A bottom-gate bottom-contact type organic thin film transistor (11) was manufactured in the same manner as in the above described Example 1, except that the coating solution (12) was used for the formation of a gate insulating layer, and characteristics of the transistor were measured and evaluated. The formed gate insulating layer had a thickness of 600 nm. The results are shown in Table 1 below.

### Example 12

In a 150 mL sample bottle, 30.72 g of the 2-heptanone solution of the polymer compound (1) obtained in the above described Synthesis Example 1, 28.57 g of the 2-heptanone solution of the polymer compound (2) obtained in the above described Synthesis Example 2, 5.93 g of the 2-heptanone solution of the polymer compound (12) obtained in the above described Synthesis Example 12, and 32.61 g of 2-heptanone were placed, and dissolved with stirring to prepare a uniform coating solution (13).

A bottom-gate bottom-contact type organic thin film transistor (12) was manufactured in the same manner as in Example 1, except that the coating solution (13) was used for the formation of a gate insulating layer, and characteristics of the transistor were measured and evaluated. The formed gate insulating layer had a thickness of 600 nm. The results are shown in Table 1 below.

### Example 13

In a 150 mL sample bottle, 30.72 g of the 2-heptanone solution of the polymer compound (1) obtained in the above described Synthesis Example 1, 28.57 g of the 2-heptanone solution of the polymer compound (2) obtained in the above described Synthesis Example 2, 5.93 g of the 2-heptanone solution of the polymer compound (13) obtained in the above described Synthesis Example 13, and 32.61 g of 2-heptanone were placed, and dissolved with stirring to prepare a uniform coating solution (14).

A bottom-gate bottom-contact type organic thin film transistor (13) was manufactured in the same manner as in Example 1, except that the coating solution (14) was used for the formation of a gate insulating layer, and characteristics of the transistor were measured and evaluated. The formed gate insulating layer had a thickness of 600 nm. The results are shown in Table 1 below.

### Example 14

In a 100 mL sample bottle, 15.06 g of the 2-heptanone solution of the polymer compound (14) obtained in the above described Synthesis Example 14, 13.91 g of the 2-heptanone solution of the polymer compound (15) obtained in the above described Synthesis Example 15, 2.90 g of the 2-heptanone solution of the polymer compound (10) obtained in the above described Synthesis Example 10, and 15.93 g of 2-heptanone were placed, and dissolved with stirring to prepare a uniform coating solution (15).

A bottom-gate bottom-contact type organic thin film transistor (14) was manufactured in the same manner as in Example 1, except that the coating solution (15) was used for the formation of a gate insulating layer, and characteristics of the transistor were measured and evaluated. The formed gate insulating layer had a thickness of 600 nm. The results are shown in Table 1 below.

### Example 15

In a 100 mL sample bottle, 15.06 g of the 2-heptanone solution of the polymer compound (14) obtained in the above described Synthesis Example 14, 13.91 g of the 2-heptanone solution of the polymer compound (15) obtained in the above described Synthesis Example 15, 2.90 g of the 2-heptanone solution of the polymer compound (13) obtained in the above described Synthesis Example 13, and 15.93 g of 2-heptanone were placed, and dissolved with stirring to prepare a uniform coating solution (16).

A bottom-gate bottom-contact type organic thin film transistor (15) was manufactured in the same manner as in Example 1, except that the coating solution (16) was used for the formation of a gate insulating layer, and characteristics of the transistor were measured and evaluated. The formed gate insulating layer had a thickness of 600 nm. The results are shown in Table 1 below.

### Example 16

In a 20 mL sample bottle, 3.23 g of the 2-heptanone solution of the polymer compound (16) obtained in the above described Synthesis Example 16, 1.05 g of the 2-heptanone solution of the polymer compound (17) obtained in the above described Synthesis Example 17, 0.57 g of the 2-heptanone solution of the polymer compound (10) obtained in the above described Synthesis Example 10, 0.05 g of MBZ-101 (sulfonic acid ester compound) (manufactured by Midori Kagaku Co., Ltd.), and 4.57 g of 2-heptanone were placed, and dissolved with stirring to prepare a uniform coating solution (17).

A bottom-gate bottom-contact type organic thin film transistor (16) was manufactured in the same manner as in Example 1, except that the coating solution (17) was used for the formation of a gate insulating layer, and characteristics of the transistor were measured and evaluated. The formed gate insulating layer had a thickness of 600 nm. The results are shown in Table 1 below.

### Example 17

In a 20 mL sample bottle, 3.23 g of the 2-heptanone solution of the polymer compound (16) obtained in the above described Synthesis Example 16, 1.05 g of the 2-heptanone solution of the polymer compound (17) obtained in the above described Synthesis Example 17, 0.57 g of the 2-heptanone solution of the polymer compound (13) obtained in the above described Synthesis Example 13, 0.05 g of MBZ-101 (sulfonic acid ester compound) (manufactured by Midori Kagaku Co., Ltd.), and 4.57 g of 2-heptanone were placed, and dissolved with stirring to prepare a uniform coating solution (18).

A bottom-gate bottom-contact type organic thin film transistor (17) was manufactured in the same manner as in Example 1, except that the coating solution (18) was used for the formation of a gate insulating layer, and characteristics of the transistor were measured and evaluated. The formed gate insulating layer had a thickness of 600 nm. The results are shown in Table 1 below.

### Example 18

In a 20 mL sample bottle, 3.00 g of the 2-heptanone solution of the polymer compound (18) obtained in the above described Synthesis Example 18 and 1.50 g of 2-heptanone were placed, and dissolved with stirring to prepare a uniform coating solution (19).

A bottom-gate bottom-contact type organic thin film transistor (18) was manufactured in the same manner as in Example 1, except that the coating solution (19) was used for the formation of a gate insulating layer, and characteristics of the transistor were measured and evaluated. The formed gate insulating layer had a thickness of 600 nm. The results are shown in Table 1 below.

### Comparative Example 1

In a 100 mL sample bottle, 8.65 g of the 2-heptanone solution of the polymer compound (4) obtained in the above described Synthesis Example 4, 11.94 g of the 2-heptanone solution of the polymer compound (5) obtained in the above described Synthesis Example 5, and 29.24 g of 2-heptanone were placed, and dissolved with stirring to prepare a uniform coating solution (20).

A bottom-gate bottom-contact type organic thin film transistor (19) was manufactured in the same manner as in Example 1, except that the coating solution (20) was used for the formation of a gate insulating layer, and characteristics of the transistor were measured and evaluated. The formed gate insulating layer had a thickness of 600 nm. The results are shown in Table 1 below.

### Comparative Example 2

In a 50 mL sample bottle, 4.30 g of the 2-heptanone solution of the polymer compound (6) obtained in the above described Synthesis Example 6, 2.55 g of the 2-heptanone solution of the polymer compound (7) obtained in the above described Synthesis Example 7, and 11.75 g of 2-heptanone were placed, and dissolved with stirring to prepare a uniform coating solution (21).

A bottom-gate bottom-contact type organic thin film transistor (20) was manufactured in the same manner as in Example 1, except that the coating solution (21) was used for the formation of a gate insulating layer, and characteristics of the transistor were measured and evaluated. The formed gate insulating layer had a thickness of 630 nm. The results are shown in Table 1 below.

TABLE 1

| | Polymer compounds used for | Carrier Mobility |
|---|---|---|
| | the gate insulating layer | (cm²/Vs) |
| Example 1 | Polymer compounds (1) and (2) | 0.46 |
| Example 2 | Polymer compounds (7) and (8) | 0.69 |
| Example 3 | Polymer compounds (1) and (8) | 0.65 |
| Example 4 | Polymer compounds (1) and (9) | 0.60 |
| Example 5 | Polymer compounds (1), (2) and (9) | 0.40 |
| Example 6 | Polymer compound (10) | 0.70 |
| Example 7 | Polymer compound (11) | 0.65 |
| Example 8 | Polymer compound (12) | 0.74 |
| Example 9 | Polymer compound (13) | 0.58 |
| Example 10 | Polymer compounds (1), (2) and (10) | 0.71 |
| Example 11 | Polymer compounds (1), (2) and (11) | 0.68 |
| Example 12 | Polymer compounds (1), (2) and (12) | 0.75 |
| Example 13 | Polymer compounds (1), (2) and (13) | 0.60 |
| Example 14 | Polymer compounds (10), (14) and (15) | 0.64 |
| Example 15 | Polymer compounds (13), (14) and (15) | 0.47 |
| Example 16 | Polymer compounds (10), (16) and (17) | 0.78 |
| Example 17 | Polymer compounds (13), (16) and (17) | 0.62 |
| Example 18 | Polymer compound (18) | 0.66 |
| Comparative | Polymer compounds (4) and (5) | 0.29 |
| Example 1 | | |
| Comparative | Polymer compounds (6) and (7) | 0.20 |
| Example 2 | | |

As is clear from Table 1, in each of Examples 1 to 18 according to the present invention, higher carrier mobility was achieved, compared with Comparative Examples 1 and 2 in which the composition of the present invention was not used.

### EXPLANATIONS OF LETTERS OR NUMERALS

1 substrate

2 gate electrode

3 gate insulating layer

4 organic semiconductor layer

5 source electrode

6 drain electrode

7 overcoat layer

10 organic thin film transistor

1. A polymer compound, comprising:
a repeating unit represented by the following formula (1); and
at least two repeating units, the repeating units being at least one selected from the group consisting of a repeating unit having a blocked isocyanato group and a repeating unit having a blocked isothiocyanato group, 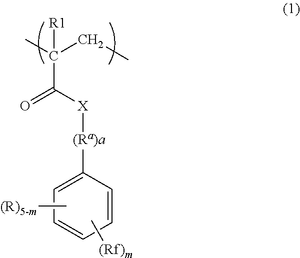
wherein, in formula (1), R¹ is a hydrogen atom or a methyl group; R is a hydrogen atom or a monovalent organic group having 1 to 20 carbon atoms; Rf is a fluorine atom or a monovalent organic group comprising a fluorine atom; R^{a} is a divalent organic group having 1 to 20 carbon atoms, and a hydrogen atom in the divalent organic group may be substituted with a fluorine atom; X is an oxygen atom or a group represented by —NR⁷—; R⁷ is a hydrogen atom or a monovalent organic group having 1 to 20 carbon atoms; a is an integer of 0 to 20; m is an integer of 1 to 5; when R^{a} is plurally present, they may be different from each other; when R is plurally present, they may be different from each other; and when Rf is plurally present, they may be different from each other.

2. The polymer compound according to claim 1, further comprising at least one repeating unit selected from the group consisting of a repeating unit having an organic group represented by the following formula (2) and a repeating unit having an organic group represented by the following formula (3): 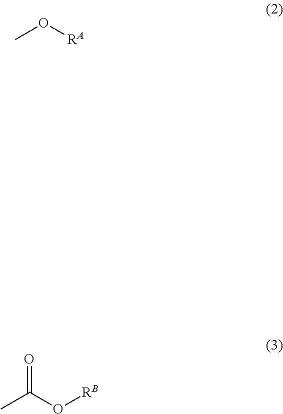
wherein, in formulae (2) and (3), R^{A} and R^{B} are each at least one monovalent organic group selected from the group consisting of a monovalent organic group represented by the following formula (4) and a monovalent organic group represented by the following formula (5): 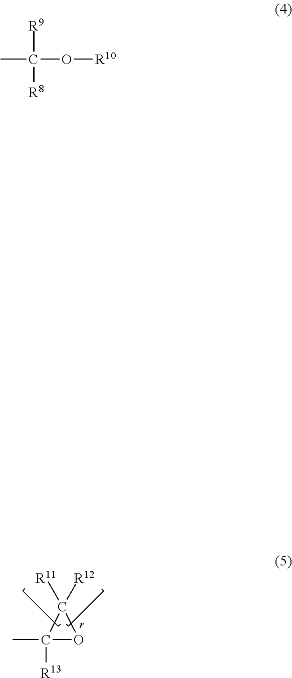
wherein, in formulae (4) and (5), R⁸, R⁹, R¹⁰, R¹¹, R¹², and R¹³ are each independently a hydrogen atom or a monovalent organic group having 1 to 20 carbon atoms; and r is an integer of 1 to 20.

3. The polymer compound according to claim 1, wherein the blocked isocyanato group or the blocked isothiocyanato group is a group represented by the following formula (6) or a group represented by the following formula (7): 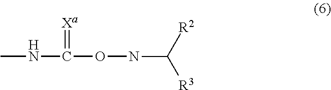
wherein, in formula (6), X^{a} is an oxygen atom or a sulfur atom; and R² and R³ may be different from each other and are each a hydrogen atom or a monovalent organic group having 1 to 20 carbon atoms, 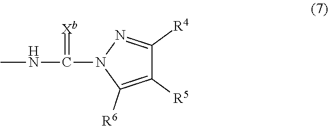
wherein, in formula (7), X^{b} is an oxygen atom or a sulfur atom; and R⁴, R⁵, and R⁶ may be different from each other and are each a hydrogen atom or a monovalent organic group having 1 to 20 carbon atoms.

4. A composition, comprising the polymer compound according to claim 1.

5. The composition according to claim 4, further comprising at least one compound selected from the group consisting of a low molecular compound comprising at least two active hydrogens and a polymer compound comprising at least two active hydrogens.

6. A cured film of the composition according to claim 4.

7. An electronic device, comprising the film according to claim 6.

8. The electronic device according to claim 7, wherein the electronic device is an organic thin film transistor.

9. An organic thin film transistor, comprising the film according to claim 6 as a gate insulating layer.

10. The organic thin film transistor according to claim 9, further comprising a cured film as an overcoat layer, wherein the cured film has a composition which comprises a polymer compound comprising:
a repeating unit represented by the following formula (1); and
at least two repeating units, the repeating units being at least one selected from the group consisting of a repeating unit having a blocked isocyanatogroup and a repeating unit having a blocked isothiocyanato group, 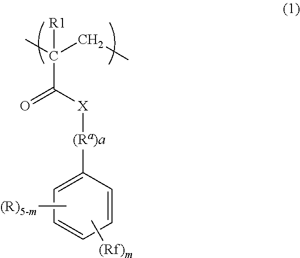
wherein, in formula (1), R¹ is a hydrogen atom or a methyl group; R is a hydrogen atom or a monovalent organic group having 1 to 20 carbon atoms; Rf is a fluorine atom or a monovalent organic group comprising a fluorine atom; R^{a} is a divalent organic group having 1 to 20 carbon atoms, and a hydrogen atom in the divalent organic group may be substituted with a fluorine atom; X is an oxygen atom or a group represented by —NR⁷—; R⁷ is a hydrogen atom or a monovalent organic group having 1 to 20 carbon atoms; a is an integer of 0 to 20; m is an integer of 1 to 5; when R^{a} is plurally present, they may be different from each other; when R is plurally present, they may be different from each other; and when Rf is plurally present, they may be different from each other.
